(19) United States
(12) Patent Application Publication
(10) Pub. No.: US 2026/0299802 A1
(43) Pub. Date: Oct. 1, 2026

(54) MEMORY SYSTEMS, CONTROL METHODS THEREOF, AND POWER LOSS PROTECTION SYSTEMS

(71) Applicant: Yangtze Memory Technologies Co., Ltd., Wuhan (CN)

(72) Inventors: Zhuangfei Qian, Wuhan (CN); Tao Xiong, Wuhan (CN); Guoqiang Wu, Wuhan (CN)

(21) Appl. No.: 19/408,067

(22) Filed: Dec. 3, 2025

(30) Foreign Application Priority Data
Mar. 25, 2025 (CN) 202510360823.3

(51) Int. Cl. G06F 3/06; G11C 14/00; H02J 7/60; H02J 7/84

(52) U.S. Cl. CPC G06F 3/0625; G06F 3/0653; G06F 3/0679; G11C 14/0018; H02J 7/60; H02J 7/84; H02J 2207/50

(57) ABSTRACT

The present disclosure provides memory systems, control methods thereof and power loss protection systems. In a memory system, a resistor-capacitor circuit comprises a capacitor configured to provide power for driving of writing data within the volatile memory device to the non-volatile memory device. A power loss protection circuit is configured to charge the capacitor. A voltage regulator circuit is configured to adjust an equivalent impedance of the resistor-capacitor circuit in response to the first control signal. A memory controller is configured to output the first control signal to the voltage regulator circuit; and is further configured to acquire a capacitance of the capacitor after adjusting the equivalent impedance by using the power loss protection circuit to determine a state of health of the capacitor.

### CROSS-REFERENCE TO RELATED APPLICATIONS

This application claims priority to and the benefit of Chinese Patent Application 202510360823.3, filed on Mar 25, 2025, which is hereby incorporated by reference in its entirety.

### FIELD OF TECHNOLOGY

Examples of the present disclosure relate to the field of semiconductor technologies, and in particular, to memory systems, control methods thereof, and power loss protection systems.

### BACKGROUND

When a memory system is abnormally powered down, in order to prevent the user data from being lost due to incomplete storage, the capacitor may be used as a power supply for providing or holding a power to ensure that the user data is written into the memory device.

### BRIEF DESCRIPTION OF THE DRAWINGS

In the drawings, like reference numerals may describe similar components in different views. Like reference numbers with different letter suffixes may represent different examples of similar components. The drawings generally illustrate various examples discussed herein by way of example and not limitation.

FIG. 1 is a first schematic structural diagram of a memory system provided by an example of the present disclosure.

FIG. 2 is a second schematic structural diagram of a memory system provided by an example of the present disclosure.

FIG. 3 is a third schematic structural diagram of a memory system provided by an example of the present disclosure.

FIG. 4 is a fourth schematic structural diagram of a memory system provided by an example of the present disclosure.

FIG. 5 is a schematic structural diagram of a voltage regulator circuit in the plurality of circuit structures shown in FIG. 2.

FIG. 6 is a schematic structural diagram of a voltage regulator circuit in the plurality of circuit structures shown in FIG. 3.

FIG. 7 is a schematic structural diagram of a voltage regulator circuit in the plurality of circuit structures shown in FIG. 4.

FIG. 8 is a fifth schematic structural diagram of a memory system provided by an example of the present disclosure.

FIG. 9 is a sixth schematic structural diagram of a memory system provided by an example of the present disclosure.

FIG. 10 is a seventh schematic structural diagram of a memory system provided by an example of the present disclosure.

FIG. 11 is an eighth schematic structural diagram of a memory system provided by an example of the present disclosure.

FIG. 12 is a schematic structural diagram of an electronic device provided by an example of the present disclosure.

FIG. 13 is a schematic structural diagram of a storage medium provided by an example of the present disclosure.

FIG. 14 is a first schematic flowchart of a control method of a memory system provided by an example of the present disclosure.

FIG. 15 is a second schematic flowchart of a control method of a memory system provided by an example of the present disclosure.

FIG. 16 is a third schematic flowchart of a control method of a memory system provided by an example of the present disclosure.

FIG. 17 is a fourth schematic flowchart of a control method of a memory system provided by an example of the present disclosure;

FIG. 18 is a fifth schematic flowchart of a memory system provided by an example of the present disclosure.

FIG. 19 is a first schematic structural diagram of a power loss protection system provided by an example of the present disclosure.

FIG. 20 is a second schematic structural diagram of a power loss protection system provided by an example of the present disclosure.

### DETAILED DESCRIPTION

The technical solutions of the present disclosure are further described in detail below with reference to the drawings and specific examples.

In the examples of the present disclosure, the terms “first”, “second”, and the like are used to distinguish similar objects, and are not used to describe a specific order or a sequential order.

In the examples of the present disclosure, the terms “A is in contact with B” comprise a case where A is in direct contact with B, or a case where other components are interposed between the A and B, and A is in indirect contact with B.

It should be understood that “some examples” or “some implementations” mentioned throughout the specification means that particular features, structures, or characteristics related to the examples are included in at least one example of the present application. Thus, “in some examples” or “in some implementations” appearing throughout the specification does not necessarily refer to the same example. Further, these particular features, structures, or characteristics may be incorporated in one or more examples in any suitable manner. It should be understood that, in various examples of the present disclosure, the sequence numbers of the above processes do not mean an order of execution sequences, and an execution sequence of each process should be determined by using a function and an intrinsic logic thereof, and should not constitute any limitation on an implementation process of the examples of the present disclosure. The above sequence numbers of the examples of the present disclosure are merely for description, and do not represent the advantages of the examples.

It should be noted that, in this specification, the terms “comprising”, “including”, or any other variant thereof are intended to cover a non-exclusive inclusion, such that a process, method, article, or apparatus that comprises a series of elements comprises not only those elements but also other elements not explicitly listed, or elements inherent to such processes, methods, articles, or apparatuses. Without further restriction, the elements defined by the statement “comprise one…” do not preclude the presence of additional identical elements in the process, method, article, or apparatus that comprises the element.

It is to be understood that the meaning of “on”, “above”, and “over” in the present disclosure should be interpreted in a broadest manner such that “on” not only indicates “on” something and there is no intervening features or layers therebetween (i.e., directly on something), but also comprises the meaning of “on” something and there is intervening features or layers therebetween.

It should be noted that although the present specification is described in terms of implementations, not every implementation comprises only an independent technical solution, and this description of the specification is merely for the sake of clarity, and those skilled in the art should use the specification as a whole, and the technical solutions in various implementations may also be combined appropriately to form other implementations that can be understood by those skilled in the art.

An example memory system (e.g., a solid state drive (SSD)) comprises volatile memory devices (e.g., dynamic random access memory (DRAM)) and non-volatile memory devices (e.g., NAND memory devices). The volatile memory device may be used to temporarily store data exchanged between the SSD and the host. The non-volatile memory devices are used to store user data.

When the memory system is abnormally powered down, in order to prevent the user data written into the non-volatile memory device from being lost due to incomplete storage, a capacitor may be used as a power supply for providing or holding a power to ensure the user data is written into the non-volatile memory device. Performance of a capacitor in a memory system is one of the important factors affecting the operation of the memory system to store data to a memory device, and the capacitor can be inspected to determine the state of health of the capacitor. However, the capacitance inspection method is single and is limited by the maximum capacitance of the capacitor, which is not conducive to improving the detection accuracy of the state of health of the capacitor, and the storage energy in the capacitor inspection process is low, which easily causes data loss. Especially when an enterprise level memory system that stores a large amount of data is abnormally powered down, the amount of charges stored in the capacitor and the stability of the charge it maintains have a particularly important impact on the amount of data stored to maintain data write operations. As such, the performance of a capacitor is one of the important factors affecting the operation of the memory system to store data to the memory device.

In order to ensure the normal operation of the capacitor, the enterprise level SSD needs to inspect the capacitor. For example, the capacitance inspection process may measure and calculate the parameters such as the capacitance of the capacitor, the capacity (loss rate) of the capacitor to store the charge, and the voltage across the capacitor, and the like. For example, the state of health of the capacitor is determined according to the change of the voltage across the capacitor before and after discharging in the buck inspection process.

It can be understood that the state of health (SOH) of the capacitor refers to the state in which the capacitor is from the beginning to the end of the life, usually represented in form of percentage. For a new energy storage device, its state of health is generally equal to 100%. As the usage time increases, its performance gradually degrades, and the state of health also decreases accordingly. The evaluation of the state of health of the capacitor is crucial for ensuring its overall charging and discharging performance, especially in applications requiring frequent charging and discharging. The state of health of the capacitor may be evaluated by various electrical parameters and temperature rise values, for example, the electrical parameters comprise capacitance, dielectric loss tangent (tan δ), and equivalent series resistance (ESR). When the capacity of the energy storage device drops to 80%, it can be considered that the energy storage system fails. Thus, by monitoring changes in these parameters, the state of health of the capacitor can be evaluated and the capacitor may be maintained or replaced in time to ensure stable operation and safety of the system.

However, the capacitor is susceptible to energy loss (i.e., the amount of charges stored by the capacitor is reduced) during the inspection process. In this way, in the case of using the charges stored in the capacitor (for example, when the memory system is abnormally powered down), due to the program time of writing data and the interval time between different programmed states written in cache region, causing the data written into the non-volatile memory device to be incomplete or causing partial data not to be written into the non-volatile memory device, thereby resulting in a problem of partial data loss. Especially in the case of abnormal power loss of the memory system in the capacitance inspection process, the degree of voltage reduction across the capacitor exceeds the expectation, the amount of lost charge is too large, and in the case of utilizing the charges stored in the capacitor, a large amount of data will be lost.

It should be noted that the capacitance inspection comprises boost inspection and buck inspection of the capacitor. Considering that the buck inspection method is easy to cause the loss of a large amount of charges of the capacitor, which is not conducive to the data retention of the capacitor in the case of abnormal power loss in the memory system, the boost inspection method can be adopted, and the probability of energy loss of the capacitor is reduced. Therefore, in the case of using the charge of the capacitor (for example, when the memory system is abnormally powered down), the power stored in the capacitor is increased based on the boost inspection mode, which will not be below the amount of charges stored initially in the capacitor, even if a portion of charges are lost after power loss, so as to continue to support data writing, and the probability of data loss can be reduced.

However, in the circuit structure where some capacitors are located, the utilization degree of the capability of the capacitor has reached the upper limit, and it is unable to support the implementation of the boost inspection operation on the capacitor, and only the buck inspection is supported; or, the utilization degree of the capability of the capacitor does not reach saturation, and only the boost inspection operation is supported under the condition that the implementation of the function of the application scenario where the capacitor is located is met. This makes it impossible to adjust the charging voltage of the capacitor based on unexpected situations in the memory system (such as abnormal power loss), resulting in overcharging of the capacitor. As such, not only the capability of the capacitor is easily exceeded, resulting the damage of the capacitor; moreover, even if the capability of the capacitor is not exceeded, the excessively high charging voltage can cause energy waste and increase the cost.

In order to solve the above problems, the present disclosure provides a memory system, a control method thereof, and a power loss protection system, which can flexibly adjust the voltage across the capacitor, improve the detection accuracy of the state of health of the capacitor, and reduce the probability of data loss in case of power loss during capacitance inspection.

In some examples, a memory system comprises a memory controller and one or more memory devices, as well as other integrated circuit structures for signal transmission.

For example, the memory device may comprise, but is not limited to, one or more of a NAND flash memory (for example, a vertical NAND flash memory), a NOR flash memory, a dynamic random access memory (DRAM), a ferroelectric random access memory (FRAM), a magnetoresistive random access memory (MRAM), a phase change random access memory (PCRAM), a resistive random access memory (RRAM), and a Nano random access memory (NRAM). Subsequent examples of the present disclosure do not limit the specific internal structure of the memory device.

For example, a memory controller may manage data in a memory device and communicate with a host. The memory controller may be configured to control operations such as reading, erasing, and programming of the memory device; may be further configured to manage various functions regarding data stored in or to be stored in the memory device, comprising, but not limited to, bad block management, garbage collection, logical-to-physical address translation, wear leveling, etc. ; and may be further configured to process error checking and correction (ECC) regarding data read from or written to the memory device.

For example, other integrated circuit structures for signal transmission may comprise circuits such as a supercapacitor, a power loss protection circuit, a buffer and a register, which is not limited in this example, and in subsequent examples, a portion of the integrated circuit structure is exemplarily described according to the technical problem to be solved by the memory system.

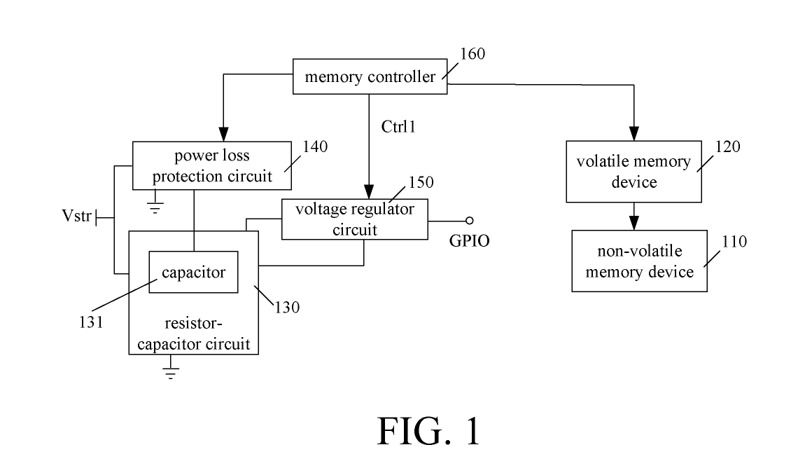

In some examples, as shown in FIGS. 1 to 11 , some examples of the present disclosure provide a memory system 100 which can flexibly adjust the voltage across the capacitor, improve the detection accuracy of the state of health of the capacitor, and reduce the probability of data loss in case of power loss during performing capacitance inspection.

In some examples, as shown in FIG. 1, the memory system 100 comprises a non-volatile memory device 110, a volatile memory device 120, a resistor-capacitor circuit 130, a power loss protection circuit 140, a voltage regulator circuit 150, and a memory controller 160.

For example, the non-volatile memory device 110 comprises a NAND memory device.

For example, the volatile memory device 120 comprises a DRAM memory device.

The resistor-capacitor circuit 130 comprises a capacitor 131 configured to provide power for driving writing data within the volatile memory device 120 to the non-volatile memory device 110.

For example, the resistor-capacitor circuit 130 may comprise a capacitor 131, such as a supercapacitor. As another example, the resistor-capacitor circuit 130 comprises a plurality of capacitors 131 connected in series. This is not limited in the examples provided in the present disclosure, and different capacitors may be provided according to actual requirements.

The power loss protection circuit 140 is coupled to the resistor-capacitor circuit 130 and is configured to charge the capacitor 131. For example, the power loss protection circuit 140 comprises a circuit having a power loss protection (PLP) function.

The voltage regulator circuit 150 is coupled to the resistor-capacitor circuit 130 and is configured to adjust an equivalent impedance of the resistor-capacitor circuit 130 in response to a first control signal Ctrl1.

The memory controller 160 is coupled to the voltage regulator circuit 150 and the power loss protection circuit 140, and is configured to output the first control signal Ctrl1 to the voltage regulator circuit 150; and is further configured to acquire the capacitance of the capacitor 131 after adjusting the equivalent impedance by using the power loss protection circuit 140, and determine the state of health of the capacitor 131.

In the above memory system 100, the inspection operation of the capacitor can be actively performed based on the first control signal Ctrl1, and the flexible control of the user on the capacitor inspection operation can be improved. By adjusting the equivalent impedance of the resistor-capacitor circuit 130 through the voltage regulator circuit 150, the voltage magnitude across the capacitor 131 (without exceeding the rated voltage of the capacitor) can be flexibly adjusted according to different requirements, and not limited by the circuit structure where the capacitor 131 is located (for example, the circuit connection relationship and structure of the resistor-capacitor circuit 130), for example, without changing other integrated circuit structures, the voltage across the capacitor 131 can be increased to different extent, or the voltage across the capacitor 131 can be reduced to different extent, so as to detect the capacity of the capacitor 131 to store charges under different conditions, and improve the detection precision of the state of health of the capacitor 131. Moreover, in the case of supporting boost inspection, even if power loss occurs in the inspection process, the amount of charges stored in the capacitor 131 is large, the non-volatile memory device 110 can be supported for data storage, and the probability of data loss is reduced.

It should be noted that the example provided in the present disclosure may perform boost inspection on the capacitor, or may perform buck inspection on the capacitor. The following example takes a case of performing boost inspection on the capacitor as an example to illustrate.

In some examples, as shown in FIG. 1, the voltage regulator circuit 150 is configured to adjust an equivalent impedance of the resistor-capacitor circuit 130 from the first resistance value R1 to the second resistance value R2 in response to the first control signal Ctrl1; the first resistance value R1 is greater than the second resistance value R2.

The power loss protection circuit 140 is configured to charge the capacitor 131 to the target voltage Vg based on the equivalent impedance of the resistor-capacitor circuit 130 being the second resistance value R2; the target voltage Vg is greater than the voltage of the resistor-capacitor circuit 130 before adjustment.

For example, the voltage regulator circuit 150 is configured to increase an equivalent impedance of the resistor-capacitor circuit 130, that is, increase the voltage across the capacitor 131 in the resistor-capacitor circuit 130, which can perform boost inspection on the capacitor 131. The power loss protection circuit 140 charges the capacitor 131 to the target voltage Vg, which can charge the capacitor 131 to be less than or equal to the rated capacitance of the capacitor 131.

In this way, in the subsequent detection process based on the higher target voltage Vg, adverse effects of other charge losses on the duration in which the capacitor 131 is stored to the target charge amount are reduced, and the determination accuracy of the state of health of the capacitor 131 storing the higher charge amount is improved. Moreover, in a case of using the charge stored by the capacitor 131 (for example, when the memory system is abnormally powered down), the power stored in the capacitor 131 is increased based on the boost inspection mode, which will not be below the amount of charges stored initially in the capacitor 131, even if a portion of charges are lost after power loss, so as to continue to support data writing, and the probability of data loss can be reduced.

It can be understood that the maximum value of “target voltage Vg” is the rated voltage of capacitor 131. The examples provided in the present disclosure can increase the voltage across the capacitor (compared to the voltage across the normally functioning capacitor, and not exceed the rated voltage) to detect. In some examples, the capacitor can only perform buck inspection (compared to the detection after the voltage across the normally functioning capacitor is reduced to a certain extent), in the case that the memory system 100 is powered down in the inspection process, the amount of charges stored in the capacitor based on the buck operation is small, and the expected amount of data written into the capacitor (the amount of data written by the program operation that can be supported by the normally functioning capacitor) cannot be met, resulting in data loss.

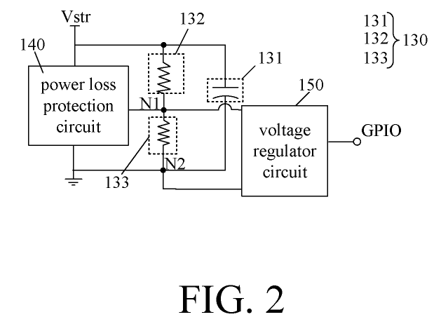

In some examples, as shown in FIGS. 2-4, the resistor-capacitor circuit 130 is coupled to the power loss protection circuit 140 through the first node N1, and is coupled to the first power supply voltage terminal (e.g., VSS) through the second node N2. It may be understood that the first power supply voltage terminal may be a power supply voltage terminal outputting a constant low level signal, for example, a power supply ground voltage VSS, a turn-off voltage VGL, or a negative power supply voltage VEE, and the like.

The resistor-capacitor circuit 130 comprises a capacitor 131, a first resistor 132, and a second resistor 133.

For example, the capacitance value of the capacitor 131 may be set according to actual requirements, which is not limited in the examples provided in the present disclosure.

One end of the first resistor 132 is coupled to the first plate of the capacitor 131, and the other end is coupled to the first node N1. For example, the first resistor 132 may comprise a fixed resistor.

One end of the second resistor 133 is coupled to the first node N1, and the other end is coupled to the second plate of the capacitor 131. For example, the second resistor 133 may comprise a fixed resistor. The resistance value of the first resistor 132 and the resistance value of the second resistor 133 may be the same or different, and may be adjusted according to actual requirements.

The voltage regulator circuit 150 is connected in parallel with at least one of the first resistor 132 or the second resistor 133 and is configured to adjust an equivalent impedance of the resistor-capacitor circuit 130.

For example, as shown in FIG. 2, the voltage regulator circuit 150 is coupled to the first node N1 and the second node N2, and is connected in parallel with the second resistor 133 to adjust an equivalent impedance of the resistor-capacitor circuit 130.

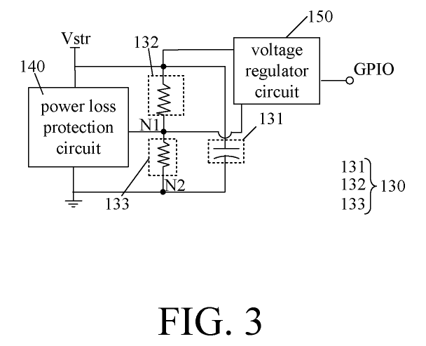

For another example, as shown in FIG. 3, the voltage regulator circuit 150 is connected in parallel with the first resistor 132 to adjust the equivalent impedance of the resistor-capacitor circuit 130.

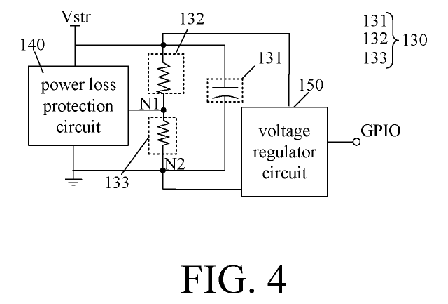

For another example, as shown in FIG. 4, the voltage regulator circuit 150 is coupled to the two plates of the capacitor 131, that is, the voltage regulator circuit 150 is connected in parallel with the overall structure of the first resistor 132 and the second resistor 133 connected in series, to adjust the equivalent impedance of the resistor-capacitor circuit 130.

Based on the electronic components comprised in the resistor-capacitor circuit 130 and the circuit connection relationship provided by the above example, the following examples illustrate that the voltage regulator circuit 150 is connected in parallel with different resistors in the resistor-capacitor circuit 130 according to the different positions where the voltage regulator circuit 150 is coupled to the resistor-capacitor circuit 130, and the equivalent resistance of the resistor-capacitor circuit 130 is changed to adjust the circuit structure of the voltage across the capacitor 131 in the resistor-capacitor circuit 130.

The following examples are illustrated exemplarily from the perspective of adjusting the equivalent impedance of the resistor-capacitor circuit 130 by different parallel connections manners of the resistor in the voltage regulator circuit 150 and the resistor in the resistor-capacitor circuit 130.

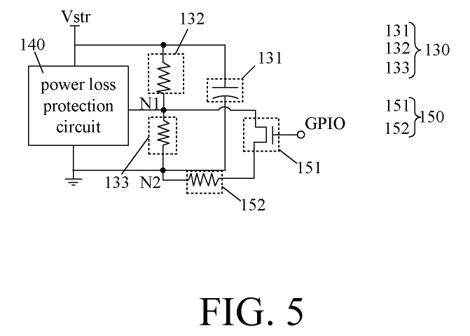

In some examples, as shown in FIG. 5, the voltage regulator circuit 150 comprises a switching transistor 151 and a third resistor 152 connected in series.

For example, the switching transistor 151 comprises an N-type transistor or a P-type transistor. It can be understood that the turn-on conditions of the N-type transistor or the P-type transistor are different. Whether the switching transistor 151 is turned on or turned off may be controlled by controlling the voltage value of the signal output by the general purpose input/output terminal GPIO. The magnitude of the voltage value of the signal output by the general purpose input/output terminal GPIO is not limited, as long as the function of the voltage regulator circuit 150 is satisfied.

A first electrode of the switching transistor 151 is coupled to the first node N1, a second electrode of the switching transistor 151 is coupled to one end of the third resistor 152, and a control electrode of the switching transistor 151 is coupled to the general purpose input/output terminal GPIO. For example, the first electrode of the switching transistor 151 may be a source electrode, and the second electrode may be a drain electrode, or the first electrode may be a drain electrode, and the second electrode may be a source electrode, which is not limited in the examples provided in the present disclosure.

The other end of the third resistor 152 is coupled to the second plate of the capacitor 131. For example, the third resistor 152 may comprise a fixed resistor, or may comprise other types of resistors, which is not limited in the present disclosure. For example, the third resistor 152 is a resistor with a fixed resistance, which facilitates controlling the variable, and is beneficial to adjusting the magnitude of the equivalent impedance of the resistor-capacitor circuit 130.

The voltage regulator circuit 150 is configured to turn on the switching transistor 151 in response to the first control signal Ctrl1 transmitted by the general purpose input/output terminal GPIO, to connect the third resistor 152 in parallel with the second resistor 133.

For example, as shown in FIG. 5, the voltage regulator circuit 150 turns on the switching transistor 151 in response to the first control signal Ctrl1 transmitted by the general purpose input/output terminal GPIO, representing that the third resistor 152 is coupled to the resistor-capacitor circuit 130. For example, the resistor-capacitor circuit 130 comprises a second resistor 133. The third resistor 152 in the voltage regulator circuit 150 is connected in parallel with the second resistor 133, which can reduce the equivalent impedance of the resistor-capacitor circuit 130 and increase the voltage across the capacitor 131. Therefore, the boost inspection can be performed on the capacitor 131 according to requirements.

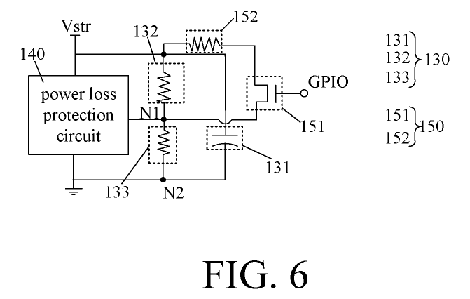

In some other examples, as shown in FIG. 6, the voltage regulator circuit 150 comprises a switching transistor 151 and a third resistor 152 connected in series.

A first electrode of the switching transistor 151 is coupled to the first node N1, a second electrode of the switching transistor 151 is coupled to one end of the third resistor 152, and a control electrode of the switching transistor 151 is coupled to the general purpose input/output terminal GPIO. For example, the switching transistor 151 comprises an N-type transistor or a P-type transistor.

The other end of the third resistor 152 is coupled to the first plate of the capacitor 131. For example, the third resistor 152 may comprise a fixed resistor, or may comprise other types of resistors, which is not limited in the present disclosure. For example, the third resistor 152 is a resistor with a fixed resistance, which facilitates controlling the variable, and is beneficial to adjusting the magnitude of the equivalent impedance of the resistor-capacitor circuit 130.

The voltage regulator circuit 150 is configured to turn on the switching transistor 151 in response to the first control signal Ctrl1 transmitted by the general purpose input/output terminal GPIO, to connect the third resistor 152 in parallel with the first resistor 132.

For example, as shown in FIG. 6, the voltage regulator circuit 150 turns on the switching transistor 151 in response to the first control signal Ctrl1 transmitted by the general purpose input/output terminal GPIO, representing that the third resistor 152 is coupled to the resistor-capacitor circuit 130. For example, the resistor-capacitor circuit 130 comprises a first resistor 132. The third resistor 152 in the voltage regulator circuit 150 is connected in parallel with the first resistor 132, which can reduce the equivalent impedance of the resistor-capacitor circuit 130 and increase the voltage across the capacitor 131. Therefore, the boost inspection can be performed on the capacitor 131 according to requirements.

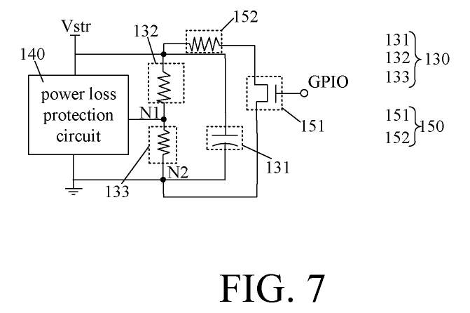

In still other examples, as shown in FIGS. 4 and 7, the voltage regulator circuit 150 comprises a switching transistor 151 and a third resistor 152 connected in series.

A first electrode of the switching transistor 151 is coupled to one end of the third resistor 152, a second electrode of the switching transistor 151 is coupled to the second node N2, and a control electrode of the switching transistor 151 is coupled to the general purpose input/output terminal GPIO. For example, the switching transistor 151 comprises an N-type transistor or a P-type transistor.

The other end of the third resistor 152 is coupled to one end of the first resistor 132.

The voltage regulator circuit 150 is configured to turn on the switching transistor 151 in response to the first control signal Ctrl1 transmitted by the general purpose input/output terminal GPIO, to connect the third resistor 152 in parallel with the first resistor 132 and the second resistor 133 connected in series.

For example, as shown in FIGS. 4 and 7 , the voltage regulator circuit 150 turns on the switching transistor 151 in response to the first control signal Ctrl1 transmitted by the general purpose input/output terminal GPIO, representing that the third resistor 152 is coupled to the resistor-capacitor circuit 130. For example, the resistor-capacitor circuit 130 comprises a first resistor 132 and a second resistor 133. The third resistor 152 in the voltage regulator circuit 150 is connected in parallel with the first resistor 132 and the second resistor 133 connected in series, which can reduce the equivalent impedance of the resistor-capacitor circuit 130 and increase the voltage across the capacitor 131. Therefore, the boost inspection can be performed on the capacitor 131 according to requirements.

The following examples are exemplarily described from the perspective that the voltage regulator circuit 150 is connected in parallel with the resistor in the resistor-capacitor circuit 130 to short-circuit this resistor to adjust the equivalent impedance of the resistor-capacitor circuit 130.

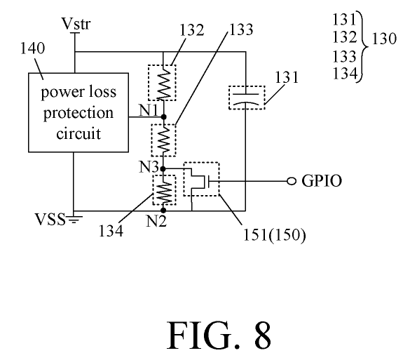

In some examples, as shown in FIG. 8, the resistor-capacitor circuit 130 is coupled to the power loss protection circuit 140 through the first node N1, and is coupled to the first power supply voltage terminal VSS through the second node N2.

The resistor-capacitor circuit 130 comprises a capacitor 131, a first resistor 132, a second resistor 133, and a fourth resistor 134.

One end of the first resistor 132 is coupled to the first plate of the capacitor 131, and the other end is coupled to the first node N1.

One end of the second resistor 133 is coupled to the first node N1, and the other end is coupled to the third node N3.

One end of the fourth resistor 134 is coupled to the third node N3, and the other end is coupled to the second plate of the capacitor 131 through the second node N2.

The voltage regulator circuit 150 comprises a switching transistor 151, a first electrode of the switching transistor 151 is coupled to the third node N3, a second electrode of the switching transistor 151 is coupled to the second node N2, and a control electrode of the switching transistor 151 is coupled to the general purpose input/output terminal GPIO.

The voltage regulator circuit 150 is configured to turn on the switching transistor 151 in response to the first control signal Ctrl1 transmitted by the general purpose input/output terminal GPIO.

For example, the voltage regulator circuit 150 is connected in parallel at two ends of the fourth resistor 134, and in the case that the switching transistor 151 is turned on in response to the first control signal Ctrl1 transmitted by the general purpose input/output terminal GPIO, the fourth resistor 134 is short-circuited, representing that the resistor-capacitor circuit 130 comprises the first resistor 132, the second resistor 133 and the capacitor 131. In this way, the resistance of the resistor-capacitor circuit 130 can be reduced, and the voltage across the capacitor 131 can be increased. Therefore, the boost inspection can be performed on the capacitor 131 according to requirements.

It may be understood that the voltage regulator circuit 150 may also be connected in parallel at two ends of the first resistor 132 or the second resistor 133, or at two ends of other electronic components connected in series in the resistor-capacitor circuit 130, which is not limited in the examples provided in the present disclosure.

Based on different examples of the positions where the voltage regulator circuit 150 and the resistor-capacitor circuit 130 are connected, in combination with the structure where the first control signal Ctrl1 is transmitted to the control electrode of the switching transistor 151 of the voltage regulator circuit 150, the resistance of the voltage regulator circuit 150 may also be adjusted by adjusting the voltage value of the first control signal Ctrl1. Further, the resistance value of the equivalent impedance of the resistor-capacitor circuit 130 is adjusted.

In some examples, the voltage regulator circuit 150 is configured to adjust the resistance value of the equivalent impedance of the resistor-capacitor circuit 130 based on the voltage value of the first control signal Ctrl1.

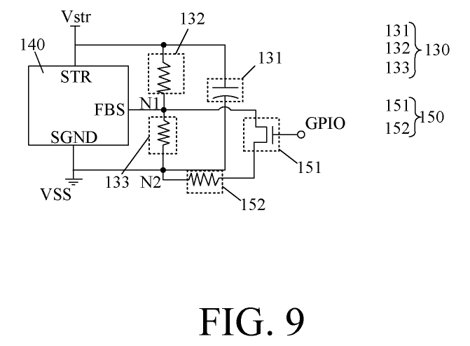

For example, as shown in FIG. 9, the voltage regulator circuit 150 comprises a switching transistor 151 and a third resistor 152 connected in series.

Based on different voltage values of the first control signal Ctrl1, the conduction degree of the switching transistor 151 may be adjusted.

For example, the switching transistor 151 comprises an N-type transistor. The voltage value of the first control signal Ctrl1 increases, the conduction degree of the switching transistor 151 increases, that is, the equivalent resistance of the switching transistor 151 decreases. The equivalent resistance of the voltage regulator circuit 150 is reduced. In this way, when the second resistor 133 and the voltage regulator circuit 150 are connected in parallel, the equivalent resistance of the second resistor 133 and the voltage regulator circuit 150 is also reduced, thereby reducing the equivalent impedance of the resistor-capacitor circuit 130. Based on this, the voltage across the capacitor 131 can be increased to some extent, which is beneficial to improving the control accuracy of the magnitude of the voltage across the capacitor 131, and can be applied to adjusting the detection of the state of health of the capacitor 131 with different capacities.

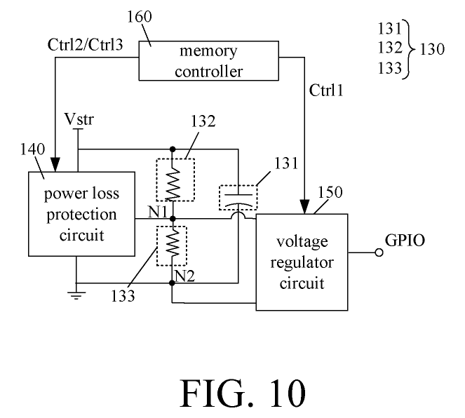

In some examples, as shown in FIG. 10, the memory controller 160 is configured to output the second control signal Ctrl2 to the power loss protection circuit 140, and control the power loss protection circuit 140 to charge the capacitor 131 after adjusting the equivalent resistance of the resistor-capacitor circuit 130 to the target voltage Vg and discharge.

The memory controller 160 is further configured to determine the state of health of the capacitor 131 according to the voltage across the discharged capacitor 131 and the target voltage Vg.

For example, compared with the initial capacitance Vin of the capacitor 131, if the target voltage Vg is greater than the initial capacitance Vin, the power loss protection circuit 140 charges the capacitor 131, and the amount of charges stored in the capacitor 131 increases.

The state of health of the capacitor 131 is determined according to the capacity calculation parameter of the capacitor 131, the target voltage Vg, and the voltage Vg_down across the discharged capacitor 131.

For example, the capacity calculation parameter of the capacitor 131 may comprise a temperature coefficient of the capacitor 131, an attribute of a dielectric material between the two plates, and the like. According to the duration needed for the capacitor 131 to store the amount of charges corresponding to the target voltage Vg under the driving of the target voltage Vg (that is, after the power supply is turned off, the voltage across the capacitor 131 is kept at Vg); and the duration needed for, after the capacitor 131 is discharged, for example, the voltage Vg_down across the capacitor 131 reaches to 0V; the time constant τ = RC is calculated. If the calculated capacitance value differs significantly from the nominal value, it indicates that the state of health of the capacitor is poor.

It should be noted that the state of health of the capacitor 131 may also be detected according to other parameters and determination logic. For example, whether the capacitor is leaking may be determined according to the voltage holding time after charging the capacitor to the amount of charges corresponding to the target voltage. Whether the capacitor is leaking may also be determined according to the speed at which the voltage across the capacitor decreases during the process of the capacitor starting to discharge from storing the amount of charges corresponding to the target voltage. This is not limited in the examples provided in the present disclosure, and may be set according to actual requirements.

In some examples, the memory controller 160 is configured to turn off the voltage regulator circuit 150 based on completion of a detection operation of the resistor-capacitor circuit 130.

As shown in FIG. 10, the memory controller 160 is further configured to output a third control signal Ctrl3 to the power loss protection circuit 140, and control the power loss protection circuit 140 to charge the capacitor 131 of the resistor-capacitor circuit 130 to an initial voltage Vin based on the voltage regulator circuit 150 being turned off; the initial voltage Vin is less than the target voltage Vg.

The power loss protection circuit 140 is further configured to maintain the non-volatile memory device 110 to perform an operation of reading/writing data for the first duration T1 by utilizing a power stored in the capacitor 131 based on the initial voltage Vin.

For example, after the capacitor 131 is inspected, it may be determined that the capacitor 131 is in a good state of health. Then, the voltage regulator circuit 150 is turned off, the capacitor 131 can be continuously charged, and the capacitor 131 is charged by using the power loss protection circuit 140, providing power for other circuits in the case that the memory system 100 is powered down. For example, the capacitor 131 maintains the non-volatile memory device 110 to perform an operation of reading/writing data for the first duration T1 by utilizing a power stored in the capacitor 131 based on the initial voltage Vin, reducing the probability of data loss or the amount of lost data.

The duration for which the non-volatile memory device 110 performs the reading/writing data operation or amount of the reading/writing data is related to the power stored based on the initial voltage Vin. Moreover, in order to reduce the probability of data loss or the amount of lost data, it is also necessary to set the initial voltage Vin in combination with the memory type of the non-volatile memory device 110. For example, the non-volatile memory device 110 comprises a NAND memory device. The NAND of the Quad-Level Cell (QLC) has a longer programming time than the NAND of the Multi-Level Cell (MLC), and a higher initial voltage Vin can be set for the NAND of the QLC, so as to increase the amount of charges stored in the capacitor 131, enabling the NAND of the QLC to perform a plurality of completed programming operations as much as possible.

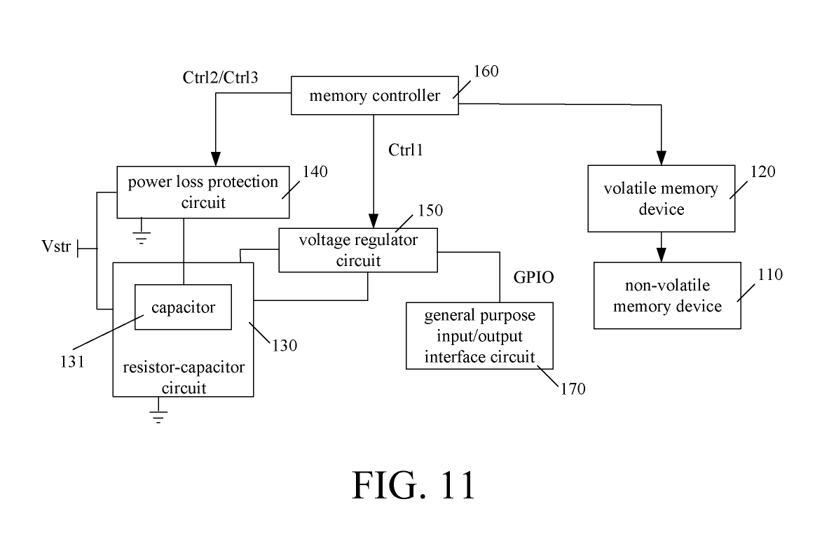

In some examples, as shown in FIG. 11, the voltage regulator circuit 150 is coupled to the general purpose input/output terminal GPIO of the general purpose input/output interface circuit 170.

The memory controller 160 is further configured to transmit the first control signal Ctrl1 to the voltage regulator circuit 150 through the general purpose input/output terminal GPIO every preset time interval T0.

For example, the general purpose input/output interface circuit 170 may comprise an interface circuit (General Purpose Input/Output, GPIO) widely used in an embedded system and a microcontroller, to implement interaction between the microcontroller and an external device. By configuring the working mode of the general purpose input/output interface circuit 170, different control signals are output from the general purpose input/output terminal GPIO.

For example, the memory controller 160 is configured to control the general purpose input/output interface circuit 170 to output the first control signal Ctrl1 from the general purpose input/output terminal GPIO to the voltage regulator circuit 150 every preset time interval T0.

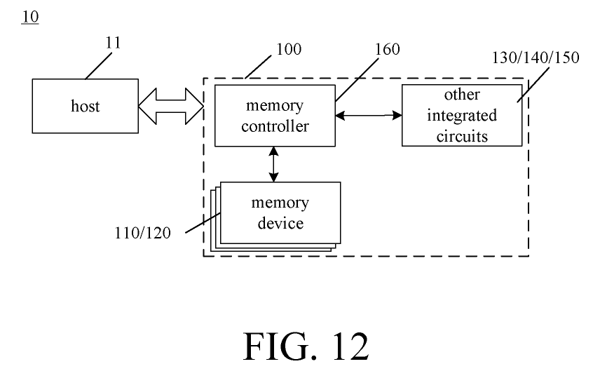

In some examples, as shown in FIG. 12, an example of the present disclosure illustrates an electronic device 10. For example, the electronic device 10 may comprise, but is not limited to, a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device therein.

Continuing to refer to FIG. 12, the electronic device 10 may comprise a host 11 and a memory system 100.

The host 11 may be a processor (for example, a central processing unit (CPU) or a system on chip (SoC) (for example, an application process (AP)) of the electronic device 10. The host 11 may be configured to send data to or receive data from the memory system 100.

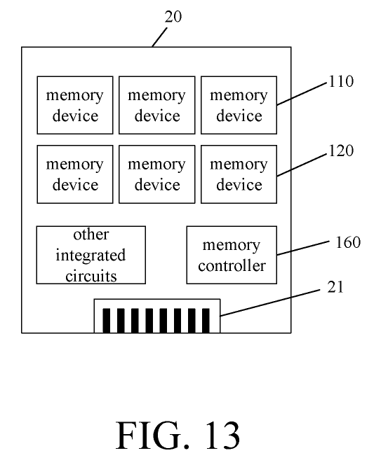

In some examples, as shown in FIG. 13, the memory controller 160, the one or more memory devices (the non-volatile memory device 110 and the volatile memory device 120 shown in FIG. 1), and other integrated circuit structures (such as the resistor-capacitor circuit 130, the power loss protection circuit 140, and the voltage regulator circuit 150 shown in FIG. 1) in the memory system 100 are integrated and packaged in the same storage medium 20. For example, the non-volatile memory device 110 comprises a NAND memory device and the volatile memory device 120 comprises a DRAM memory device. In this way, it is beneficial for applying the memory system 100 to different types of end electronic products.

For example, as shown in FIG. 13, the present disclosure provides a readable storage medium 20. The readable storage medium 20 comprises a stored computer program or instruction; and the computer program or the instruction, when executed, controls a device where the computer readable storage medium is located to implement the control method of the memory system provided in any one of the following examples.

For example, the types of the readable storage medium 20 comprise another type of storage device such as universal flash storage (UFS) or embedded multi media card (eMMC).

For example, there may be a plurality of ways of the integrated circuit of the readable storage medium 20, which may be a memory card formed by integrating a single memory device 110 and a memory controller 160 together. For example, the memory card may comprise one or more types of storage devices of a personal computer memory card international association (PC) card, a CF card, a smart media (SM) card, a memory stick, a multi-media card (MMC), an RS-MMC (Reduced-Size MMC), an MMC micro), an SD card (SD, miniSD, microSD, SDHC (Secure Digital High Capacity)), and a UFS.

The memory card further comprises a memory card connector 21. The memory card connector is configured to couple the memory card with a host (e.g., host 11 in FIG. 12). For example, the memory card connector 21 comprises a gold finger.

For another example, the way of the integrated circuit of the readable storage medium 20 may also be a SSD formed by integrating a plurality of memory devices (a plurality of non-volatile memory devices 110 and a plurality of volatile memory devices 120) and a memory controller 160.

For example, SSD 420 also comprises SSD connector 21. The SSD connector 21 is configured to couple the SSD 420 with a host (e.g., host 11 in FIG. 12). For example, SSD connector 21 comprises a gold finger.

It will be appreciated that at least one of the storage capacity and operating speed of the SSD is greater than that of the memory card.

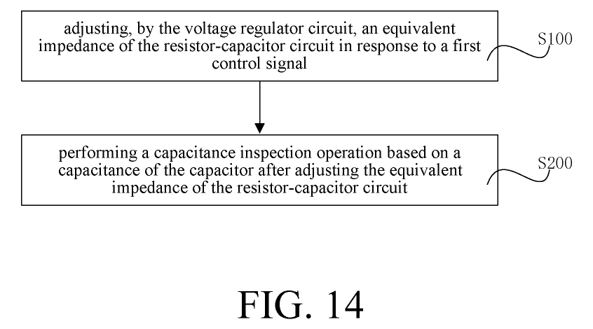

In some other examples, as shown in FIGS. 14 to 18 , some examples of the present disclosure provide a control method of a memory system 100. For example, as shown in FIG. 1, the memory system 100 comprises a non-volatile memory device 110, a volatile memory device 120, a memory controller 160, a resistor-capacitor circuit 130, a power loss protection circuit 140, and a voltage regulator circuit 150. The non-volatile memory device 110 and the volatile memory device 120 are coupled to a memory controller 160. The resistor-capacitor circuit 130 is coupled to the non-volatile memory device 110, the volatile memory device 120, the memory controller 160, the power loss protection circuit 140, and the voltage regulator circuit 150.

As shown in FIG. 14, the control method comprises S100 and S200.

S100: adjusting, by the voltage regulator circuit 150, an equivalent impedance of the resistor-capacitor circuit 130 in response to a first control signal Ctrl1.

For example, the voltage regulator circuit 150 is connected in parallel with the resistor of the resistor-capacitor circuit 130, as shown in FIGS. 2 to 4 , the voltage regulator circuit 150 is connected in parallel with at least one of the first resistor 132 or the second resistor 133 in the resistor-capacitor circuit 130 to adjust the equivalent impedance of the resistor-capacitor circuit 130.

For example, the first resistor 132 may comprise a fixed resistor. The second resistor 133 may comprise a fixed resistor. The resistance value of the first resistor 132 and the resistance value of the second resistor 133 may be the same or different, and may be adjusted according to actual requirements.

S200: Performing a capacitance inspection operation based on a capacitance of the capacitor 131 after adjusting the equivalent impedance of the resistor-capacitor circuit 130.

For example, the equivalent impedance of the resistor-capacitor circuit 130 is adjusted to increase or decrease, for example, the equivalent impedance of the resistor-capacitor circuit 130 is decreased, the voltage across the capacitor 131 of the resistor-capacitor circuit 130 is increased, and the capacitance of the capacitor 131 is increased. In this way, the boost inspection can be performed on the capacitor 131, the probability of energy loss in the inspection process of the capacitor 131 is reduced, and the detection precision of the state of health of the capacitor 131 is improved.

In the above memory system 100, the inspection operation of the capacitor 131 can be actively performed based on the first control signal Ctrl1, and the flexible control of the user on the inspection operation of the capacitor 131 can be improved. By adjusting the equivalent impedance of the resistor-capacitor circuit 130 through the voltage regulator circuit 150, the voltage magnitude across the capacitor 131 (without exceeding the rated voltage of the capacitor) can be flexibly adjusted according to different requirements, and not limited by the circuit structure where the capacitor 131 is located (for example, the circuit connection relationship and structure of the resistor-capacitor circuit 130), for example, without changing other integrated circuit structures, the voltage across the capacitor 131 can be increased to different extent, or the voltage across the capacitor 131 can be reduced to different extent, so as to detect the capacity of the capacitor 131 to store charges under different conditions, and improve the detection precision of the state of health of the capacitor 131. Moreover, in the case of supporting boost inspection, even if power loss occurs in the inspection process, the amount of charges stored in the capacitor 131 is large, the non-volatile memory device 110 can be supported for data storage, and the probability of data loss is reduced.

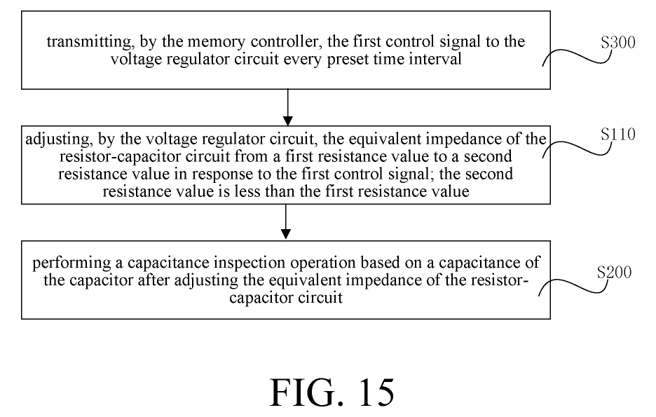

In some examples, as shown in FIG. 15, the control method further comprises: S300.

S300: transmitting, by the memory controller 160, the first control signal Ctrl1 to the voltage regulator circuit 150 every preset time interval T0.

In operation S100, adjusting, by the voltage regulator circuit 150, an equivalent impedance of the resistor-capacitor circuit 130 in response to a first control signal Ctrl1 comprises S110.

S110: adjusting, by the voltage regulator circuit 150, the equivalent impedance of the resistor-capacitor circuit 130 from a first resistance value R1 to a second resistance value R2 in response to the first control signal Ctrl1; the second resistance value R2 is less than the first resistance value R1.

For example, the memory controller 160 may periodically control the general purpose input/output interface circuit 170 to output the first control signal Ctrl1. For example, the first control signal Ctrl1 is transmitted to the voltage regulator circuit 150 every preset time interval T0, the capacitor 131 in the resistor-capacitor circuit 130 is inspected, and timely detection of the state of health of the capacitor 131 is improved.

For example, the voltage regulator circuit 150 is configured to increase the equivalent impedance of the resistor-capacitor circuit 130, that is, increase the voltage across the capacitor 131 in the resistor-capacitor circuit 130, and can perform boost inspection on the capacitor 131. The power loss protection circuit 140 charges the capacitor 131 to the target voltage Vg, which can charge the capacitor 131 to be less than or equal to the rated capacitance of the capacitor 131.

In this way, during the subsequent detection based on the higher target voltage Vg, it is beneficial to improve the determination accuracy of the state of health of the capacitor 131 storing the higher amount of charges, and is beneficial to design the storage energy of the capacitor 131 under the power loss condition of the memory system 100, so as to provide sufficient amount of charges to support data writing.

It can be understood that the maximum value of “target voltage Vg” is the rated voltage of capacitor 131. The examples provided in the present disclosure can increase the voltage across the capacitor (compared to the voltage across the normally functioning capacitor, and not exceed the rated voltage) to detect. In some examples, the capacitor can only perform buck inspection (compared to the detection after the voltage across the normally functioning capacitor is reduced to some extent), in the case that the memory system 100 is powered down in the inspection process, the amount of charges stored in the capacitor based on the buck operation is small, and the expected amount of data written into the capacitor (the amount of data written by the program operation that can be supported by the normally functioning capacitor) cannot be met, resulting in data loss.

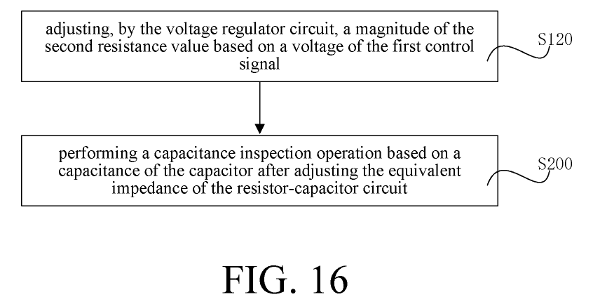

In some examples, as shown in FIG. 16, in operation S100, adjusting, by the voltage regulator circuit 150, an equivalent impedance of the resistor-capacitor circuit 130 in response to a first control signal Ctrl1 comprises S120.

S120: adjusting, by the voltage regulator circuit 150, a magnitude of the second resistance value R2 based on a voltage of the first control signal Ctrl1.

For example, as shown in FIG. 9, the voltage regulator circuit 150 comprises a switching transistor 151 and a third resistor 152 connected in series.

Based on different voltage values of the first control signal Ctrl1, the conduction degree of the switching transistor 151 may be adjusted. For example, the switching transistor 151 comprises an N-type transistor. The voltage value of the first control signal Ctrl1 increases, the conduction degree of the switching transistor 151 increases, and the equivalent resistance of the switching transistor 151 decreases. The equivalent resistance of the voltage regulator circuit 150 is reduced. In this way, when the second resistor 133 and the voltage regulator circuit 150 are connected in parallel, the equivalent resistance (that is, the second resistance value R2) of the second resistor 133 and the voltage regulator circuit 150 is also reduced, thereby reducing the equivalent impedance (that is, the second resistance value R2) of the resistor-capacitor circuit 130. Based on this, the voltage across the capacitor 131 can be increased to some extent, which is beneficial to improving the control accuracy of the magnitude of the voltage across the capacitor 131, and can be applied to the detection of the state of health of the capacitor 131 with different capacities.

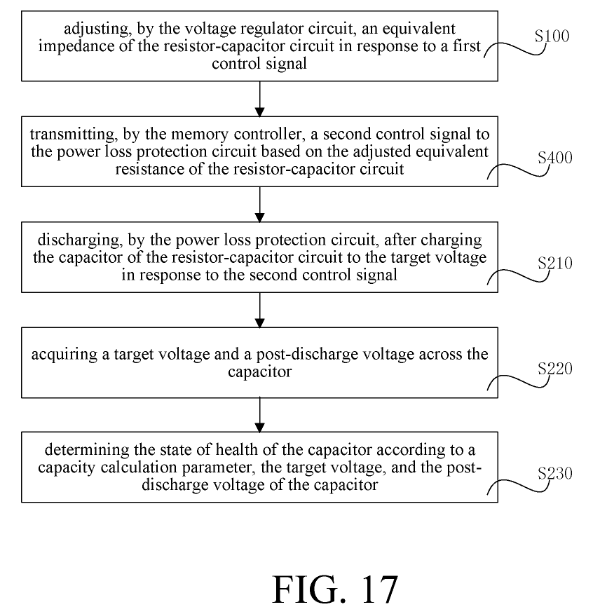

In some examples, as shown in FIG. 17, the control method comprises S400.

S400: transmitting, by the memory controller 160, a second control signal Ctrl2 to the power loss protection circuit 140 based on the adjusted equivalent resistance of the resistor-capacitor circuit 130.

The above operation S200: the determining a state of health of the capacitor 131 based on the capacitance of the capacitor 131 after adjusting the equivalent impedance of the resistor-capacitor circuit 130 comprises S210 to S230.

S210: discharging, by the power loss protection circuit 140, after charging the capacitor 131 of the resistor-capacitor circuit 130 to the target voltage Vg in response to the second control signal Ctrl2.

S220: acquiring a target voltage Vg and a post-discharge voltage Vg_down across the capacitor 131.

S230: determining the state of health of the capacitor 131 according to the capacity calculation parameter, the target voltage Vg, and the post-discharge voltage Vg_down of the capacitor 131.

For example, after the voltage regulator circuit adjusts the equivalent resistance of the resistor-capacitor circuit 130 in response to the first control signal Ctrl1, the power loss protection circuit 140 discharges after charging the capacitor 131 of the resistor-capacitor circuit 130 to the target voltage Vg in response to the second control signal Ctrl2.

The memory controller 160 acquires the target voltage Vg and the post-discharge voltage Vg_down across the capacitor 131. In addition, the memory controller 160 may calculate the time constant τ = RC according to the duration needed for the capacitor 131 to store the amount of charges corresponding to the target voltage Vg under the driving of the target voltage Vg (that is, after the power supply is turned off, the voltage across the capacitor 131 is kept at Vg); and the duration needed for, after the capacitor 131 is discharged, for example, the voltage Vg_down across the capacitor 131 reaches to 0V. If the calculated capacitance value differs significantly from the nominal value, it indicates that the state of health of the capacitor is poor.

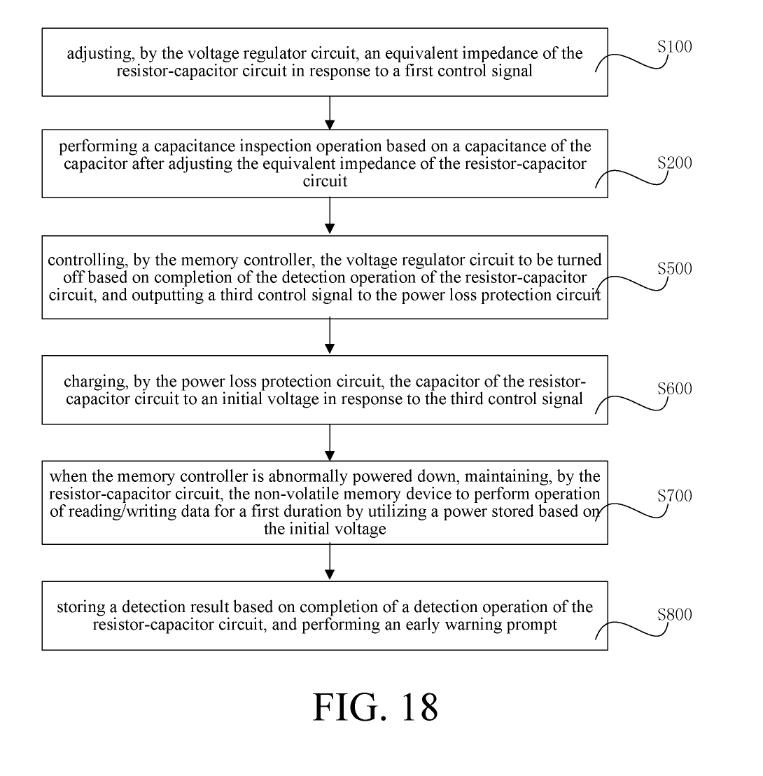

In some examples, as shown in FIG. 18, the control method further comprises S500 to S700.

S500: controlling, by the memory controller 160, the voltage regulator circuit 150 to be turned off based on completion of the detection operation of the resistor-capacitor circuit 130, and outputting a third control signal Ctrl3 to the power loss protection circuit 140.

For example, the memory controller 160 may determine that the detection operation of the resistor-capacitor circuit 130 ends according to the respective flag bit state change corresponding to functions. Then, the voltage regulator circuit 150 is controlled to be turned off and the third control signal Ctrl3 is outputted to the power loss protection circuit 140.

S600: charging, by the power loss protection circuit 140, the capacitor 131 of the resistor-capacitor circuit 130 to the initial voltage Vin in response to the third control signal Ctrl3.

For example, the initial voltage Vin is a voltage value that is preset by the memory system 100 and that meets a required function operation, and when the capacitor 131 is charged based on the initial voltage Vin, the capacitor 131 can provide a standby power that meets a certain functional requirement when the memory system 100 is powered down. The magnitude of the initial voltage Vin may be adjusted according to actual conditions, which is not limited in the examples provided in the present disclosure.

S700: When the memory controller 160 is abnormally powered down, the resistor-capacitor circuit 130 maintains the non-volatile memory device 110 to perform operation of reading/writing data for a first duration T1 by utilizing a power stored based on the initial voltage Vin.

For example, when the memory system 100 is abnormally powered down, the resistor-capacitor circuit 130 maintains the non-volatile memory device 110 to perform operation of reading/writing data for a first duration T1 by utilizing a power stored based on the initial voltage Vin. The duration for which the non-volatile memory device 110 performs the reading/writing data operation or amount of the reading/writing data is related to the power stored based on the initial voltage Vin.

The magnitude of the initial voltage Vin may be set according to actual requirements. For example, the non-volatile memory device 110 comprises a NAND memory device. Considering the time needed for the memory devices of different storage types to perform the completed programming operation, the programming time needed for the NAND of the QLC to perform one programming operation is longer compared with the time that the NAND of the MLC takes to perform one programming operation, and in the case of power loss, a larger power is required to support the NAND of the QLC for data storage, and thus a higher initial voltage Vin may be set to increase the amount of charges stored in the capacitor 131, enabling the NAND of the QLC to perform a plurality of completed programming operations as much as possible.

In some examples, as shown in FIG. 18, the control method further comprises S800.

S800: storing a detection result based on completion of a detection operation of the resistor-capacitor circuit 130, and performing an early warning prompt.

For example, after the capacitor 131 in the resistor-capacitor circuit 130 is inspected, an early warning prompt is performed according to whether the state of health of the capacitor 131 meets the requirement. For example, the results and parameters of the state of health of the capacitor 131 are displayed, and the capacitor 131 with poor state of health is marked to prompt the user to change the capacitor 131.

The manner of early warning is not limited in the example provided in the present disclosure, and different manners of early warning prompt may be performed according to the application scenario and the detection phase of the memory system 100.

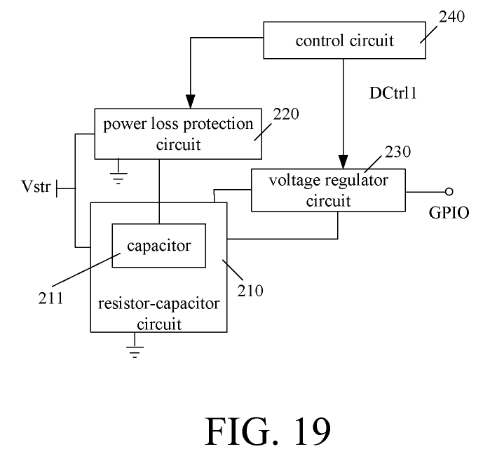

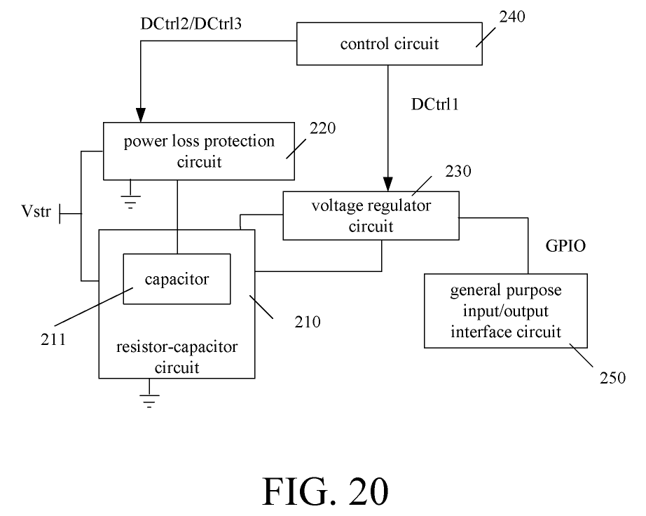

In yet another example, as shown in FIGS. 19 and 20 , an example of the present disclosure provides a power loss protection system 200, which can flexibly adjust the voltage across the capacitor, improve the detection accuracy of the state of health of the capacitor, and reduce the probability of data loss in case of power loss during capacitance inspection. It should be noted that the power loss protection system provided in this example may be applied to different types of electronic devices, thereby improving power loss protection performance.

For example, as shown in FIG. 19, the power loss protection system comprises: a resistor-capacitor circuit 210, a power loss protection circuit 220, a voltage regulator circuit 230, and a control circuit 240.

The resistor-capacitor circuit 210 comprises a capacitor 211 configured to provide a power. For example, the resistor-capacitor circuit 210 may comprise a capacitor 211, such as a supercapacitor. As another example, the resistor-capacitor circuit 210 comprises a plurality of capacitors 211 connected in series. This is not limited in the examples provided in the present disclosure, and different capacitors may be set according to the actual required power energy.

The power loss protection circuit 220 is coupled to the resistor-capacitor circuit 210 and is configured to charge the capacitor 211. For example, the power loss protection circuit 220 comprises a circuit having a Power Loss Protection (PLP) function.

The voltage regulator circuit 230 is coupled to the resistor-capacitor circuit 210 and is configured to adjust an equivalent impedance of the resistor-capacitor circuit 210 in response to the first control signal DCtrl1.

The control circuit 240 is coupled to the voltage regulator circuit 230 and the power loss protection circuit 220, and is configured to output the first control signal DCtrl1 to the voltage regulator circuit 230; and is further configured to acquire the capacitance of the capacitor 211 after adjusting the equivalent impedance by using the power loss protection circuit 220 to determine the state of health of the capacitor 211.

In the above power loss protection system 200, the inspection operation of the capacitor 211 can be actively performed based on the first control signal DCtrl1, and the flexible control of the user on the inspection operation of the capacitor 211 can be improved. By adjusting the equivalent impedance of the resistor-capacitor circuit 210 through the voltage regulator circuit 230, the voltage magnitude across the capacitor 211 (without exceeding the rated voltage of the capacitor) can be flexibly adjusted according to different requirements, and not limited by the circuit structure where the capacitor 211 is located (for example, the circuit connection relationship and structure of the resistor-capacitor circuit 210), for example, without changing other integrated circuit structures, the voltage across the capacitor 211 can be increased to different extent, or the voltage across the capacitor 211 can be reduced to different extent, so as to detect the capacity of the capacitor 211 to store charges under different conditions, and improve the detection precision of the state of health of the capacitor 211. Moreover, in the case of supporting boost inspection, even if power loss occurs in the inspection process, the amount of charges stored in the capacitor 211 is large, the operation of other integrated circuit structures in the power loss protection system can be supported for a period of time, and the product performance of the power loss protection system is improved.

In some examples, the voltage regulator circuit 230 is configured to adjust an equivalent impedance of the resistor-capacitor circuit 210 from the first resistance value DR1 to the second resistance value DR2 in response to the first control signal DCtrl1; the first resistance value DR1 is greater than the second resistance value DR2.

The power loss protection circuit 220 is configured to charge the capacitor 211 to the target voltage DVg based on the equivalent impedance of the resistor-capacitor circuit 210 being the second resistance value DR2; the target voltage DVg is greater than the voltage of the resistor-capacitor circuit 210 before adjustment.

For example, the voltage regulator circuit 230 is configured to increase an equivalent impedance of the resistor-capacitor circuit 210, that is, increase the voltage across the capacitor 211 in the resistor-capacitor circuit 210, enabling to perform boost inspection on the capacitor 211. The power loss protection circuit 220 charges the capacitor 211 to target voltage DVg, enabling the capacitor 211 to be charged to less than or equal to the rated capacitance of the capacitor 211.

In this way, during the subsequent detection based on the higher target voltage DVg, it is beneficial to improve the determination accuracy of the state of health of the capacitor 211 storing the higher amount of charges, and is beneficial to design the storage energy of the capacitor 211 under the power loss condition of the power loss protection system 200, so as to provide sufficient amount of charges to support data writing.

It can be understood that the maximum value of “target voltage DVg” is the rated voltage of the capacitor 211. The examples provided in the present disclosure can increase the voltage across the capacitor (compared to the voltage across the normally functioning capacitor, and not exceed the rated voltage) to detect. In some examples, the capacitor can only perform buck inspection (compared to the detection after the voltage across the normally functioning capacitor is reduced to a certain extent), in the case that power loss occurs in the inspection process, the amount of charges stored in the capacitor based on the buck operation is small, and other integrated circuits cannot be supported to store the expected amount of data (the amount of data that can be stored in the normally functioning capacitor), resulting in data loss.

It should be noted that, in addition to the power loss protection, the power loss protection system provided in this example may implement other functions according to different application scenarios, the other functions and the corresponding circuit structures of the power loss protection system are not limited in the present disclosure, and only some circuit structures implementing the power loss protection function are exemplarily described.

For example, some circuit structures implementing the power loss protection function in the power loss protection system may be the same as the connection relationship between some circuit structures implementing power loss protection in the memory system 100 provided by the above example of the present disclosure and the connection relationship of the main electronic components in each circuit. The following examples refer to connection relationships between different circuits and different electronic components shown in FIGS. 2 to 9 , to illustrate some circuit structures for implementing the power loss protection function in the power loss protection system more clearly and briefly.

In some examples, the electronic components and their connection relationships in the resistor-capacitor circuit 210 in the power loss protection system shown in FIG. 19 may be the same as those in the resistor-capacitor circuit 130 in the memory system 100 shown in FIGS. 2 to 4 . Furthermore, the connection relationship between the resistor-capacitor circuit 210 and the voltage regulator circuit 230 in the power loss protection system shown in FIG. 19 may be the same as the connection relationship between the voltage regulator circuit 150 and the resistor-capacitor circuit 130 in the memory system 100 shown in FIGS. 2 to 4 .

For example, similar to the electronic components and their connection relationships in the resistor-capacitor circuit 130 in the memory system 100 shown in FIGS. 2 to 4 , the resistor-capacitor circuit 210 in the power loss protection system is coupled to the power loss protection circuit 220 through the first node N1, and is coupled to the first power supply voltage terminal (e.g., VSS) through the second node N2.

The resistor-capacitor circuit 210 comprises a capacitor (such as the capacitor 131 shown in FIGS. 2 to 4 ), a first resistor (such as the first resistor 132 shown in FIGS. 2 to 4 ), and a second resistor (such as the second resistor 133 shown in FIGS. 2 to 4 ).

One end of the first resistor is coupled to the first plate of the capacitor, and the other end is coupled to the first node N1. One end of the second resistor is coupled to the first node N1, and the other end is coupled to the second plate of the capacitor. For example, the first resistor may comprise a fixed resistor. The second resistor may comprise a fixed resistor. The resistance value of the first resistor and the resistance value of the second resistor may be the same or different, and may be adjusted according to actual requirements.

The voltage regulator circuit 230 is connected in parallel with at least one of the first resistor or the second resistor and is configured to adjust an equivalent impedance of the resistor-capacitor circuit 210.

For example, similar to the connection relationship between the voltage regulator circuit 150 and the resistor-capacitor circuit 130 in the memory system 100 shown in FIG. 2, the voltage regulator circuit 230 in the power loss protection system is coupled to the first node N1 and the second node N2, that is, connected in parallel with the second resistor, to adjust the equivalent impedance of the resistor-capacitor circuit 210.

For another example, similar to the connection relationship between the voltage regulator circuit 150 and the resistor-capacitor circuit 130 in the memory system 100 shown in FIG. 3, the voltage regulator circuit 230 in the power loss protection system is connected in parallel with the first resistor to adjust the equivalent impedance of the resistor-capacitor circuit 210.

For another example, similar to the connection relationship between the voltage regulator circuit 150 and the resistor-capacitor circuit 130 in the memory system 100 shown in FIG. 4, the voltage regulator circuit 230 in the power loss protection system is coupled to the two plates of the capacitor 211, that is, connected in parallel with the overall structure of the first resistor and the second resistor connected in series, to adjust the equivalent impedance of the resistor-capacitor circuit 210.

In some examples, the electronic components and their connection relationships in the voltage regulator circuit 230 in the power loss protection system shown in FIG. 19 may be the same as those in the voltage regulator circuit 150 in the memory system 100 shown in FIG. 5.

For example, similar to the electronic components and their connection relationships in the voltage regulator circuit 150 in the memory system 100 shown in FIG. 5, the voltage regulator circuit 230 in the power loss protection system comprises a switching transistor (such as the switching transistor 151 shown in FIG. 5) and a third resistor (such as the third resistor 152 shown in FIG. 5) connected in series.

A first electrode of the switching transistor is coupled to the first node N1, a second electrode of the switching transistor is coupled to one end of the third resistor, and a control electrode of the switching transistor is coupled to the general purpose input/output terminal GPIO. For example, the switching transistor comprises an N-type transistor or a P-type transistor.

The other end of the third resistor is coupled to the second plate of the capacitor 211.

The voltage regulator circuit 230 is configured to turn on the switching transistor in response to the first control signal DCtrl1 transmitted by the general purpose input/output terminal GPIO, to connect the third resistor in parallel with the second resistor (such as the second resistor 133 shown in FIG. 5).

In this way, the voltage regulator circuit 230 turns on the switching transistor in response to the first control signal DCtrl1 transmitted by the general purpose input/output terminal GPIO, indicating that the third resistor is coupled to the resistor-capacitor circuit 210. For example, the resistor-capacitor circuit 210 comprises a second resistor (such as the second resistor 133 shown in FIG. 5). The third resistor in the voltage regulator circuit 230 is connected in parallel with the second resistor, which can reduce the equivalent impedance of the resistor-capacitor circuit 210 and increase the voltage across the capacitor 211. Therefore, boost inspection can be performed on the capacitor 211 according to requirements.

In other examples, the electronic components and their connection relationships in the voltage regulator circuit 230 in the power loss protection system shown in FIG. 19 may be the same as those in the voltage regulator circuit 150 in the memory system 100 shown in FIG. 6.

For example, similar to the electronic components and their connection relationships in the voltage regulator circuit 150 in the memory system 100 shown in FIG. 6, the voltage regulator circuit 230 in the power loss protection system comprises a switching transistor (such as the switching transistor 151 shown in FIG. 6) and a third resistor (such as the third resistor 152 shown in FIG. 6) connected in series. A first electrode of the switching transistor is coupled to the first node N1, a second electrode of the switching transistor is coupled to one end of the third resistor, and a control electrode of the switching transistor is coupled to the general purpose input/output terminal GPIO. For example, the switching transistor comprises an N-type transistor or a P-type transistor.

The other end of the third resistor is coupled to the first plate of the capacitor 211.

The voltage regulator circuit 230 is configured to turn on the switching transistor in response to the first control signal transmitted by the general purpose input/output terminal GPIO, to connect the third resistor in parallel with the first resistor (such as the first resistor 132 shown in FIG. 6).

The above voltage regulator circuit 230 turns on the switching transistor in response to the first control signal DCtrl1 transmitted by the general purpose input/output terminal GPIO, characterizing that the third resistor is coupled to the resistor-capacitor circuit 210. For example, the resistor-capacitor circuit 210 (such as the first resistor 130 shown in FIG. 6) comprises a first resistor (such as the first resistor 132 shown in FIG. 6). The third resistor in the voltage regulator circuit 230 is connected in parallel with the first resistor, which can reduce the equivalent impedance of the resistor-capacitor circuit 210 and increase the voltage across the capacitor 211. Therefore, boost inspection can be performed on the capacitor 211 according to requirements.

In still other examples, the electronic components and their connection relationships in the voltage regulator circuit 230 in the power loss protection system shown in FIG. 19 may be the same as those in the voltage regulator circuit 150 in the memory system 100 shown in FIG. 7.

For example, similar to the electronic components and their connection relationships in the voltage regulator circuit 150 in the memory system 100 shown in FIG. 7, the voltage regulator circuit 230 in the power loss protection system comprises a switching transistor (such as the switching transistor 151 shown in FIG. 7) and a third resistor (such as the third resistor 152 shown in FIG. 7) connected in series.

A first electrode of the switching transistor is coupled to one end of the third resistor, a second electrode of the switching transistor is coupled to the second node N2, and a control electrode of the switching transistor is coupled to the general purpose input/output terminal GPIO. For example, the switching transistor comprises an N-type transistor or a P-type transistor.

The other end of the third resistor is coupled to one end of a first resistor (such as the first resistor 132 shown in FIG. 7).

The voltage regulator circuit 230 is configured to turn on the switching transistor in response to the first control signal Ctrl1 transmitted by the general purpose input/output terminal GPIO, to connect the third resistor in parallel with the first resistor and the second resistor connected in series.

In this way, the voltage regulator circuit 230 turns on the switching transistor in response to the first control signal DCtrl1 transmitted by the general purpose input/output terminal GPIO, characterizing that the third resistor is coupled to the resistor-capacitor circuit 210 (such as the resistor-capacitor circuit 130 shown in FIG. 7). For example, the resistor-capacitor circuit 210 comprises a first resistor (such as the first resistor 132 shown in FIG. 7) and a second resistor (such as the second resistor 133 shown in FIG. 7). The third resistor in the voltage regulator circuit 230 is connected in parallel with the first resistor and the second resistor connected in series, which can reduce the equivalent impedance of the resistor-capacitor circuit 210 and increase the voltage across the capacitor 211. Therefore, boost inspection can be performed on the capacitor 211 according to requirements.

In still other examples, the electronic components and their connection relationships in the voltage regulator circuit 230 in the power loss protection system as shown in FIG. 19 may be the same as those in the voltage regulator circuit 150 in the memory system 100 shown in FIG. 8. Moreover, the electronic components and their connection relationships in the resistor-capacitor circuit 210 in the power loss protection system as shown in FIG. 19 may be the same as those in the resistor-capacitor circuit 130 in the memory system 100 shown in FIG. 8.

For example, similar to the electronic components and their connection relationships in the resistor-capacitor circuit 130 in the memory system 100 shown in FIG. 8, the resistor-capacitor circuit 210 in the power loss protection system is coupled to the power loss protection circuit 220 through the first node N1, and is coupled to the first power supply voltage terminal (e.g., VSS) through the second node N2. It may be understood that the first power supply voltage terminal may be a power supply voltage terminal outputting a constant low-level signal, for example, a power supply ground voltage VSS, a turn-off voltage VGL, or a negative power supply voltage VEE.

For example, the resistor-capacitor circuit 210 comprises a capacitor 211 (such as the capacitor 131 shown in FIG. 8), a first resistor (such as the first resistor 132 shown in FIG. 8), a second resistor (such as the second resistor 133 shown in FIG. 8), and a fourth resistor (such as the fourth resistor 134 shown in FIG. 8). One end of the first resistor is coupled to the first plate of the capacitor 211, and the other end is coupled to the first node N1.

One end of the second resistor is coupled to the first node N1, and the other end is coupled to the third node N3.

One end of the fourth resistor is coupled to the third node N3, and the other end is coupled to the second plate of the capacitor 211 through the second node N2.

For example, similar to the electronic components and their connection relationships in the voltage regulator circuit 150 in the memory system 100 shown in FIG. 8, the voltage regulator circuit 230 in the power loss protection system comprises a switching transistor (such as the switching transistor 151 shown in FIG. 8), a first electrode of the switching transistor is coupled to the third node N3, a second electrode of the switching transistor is coupled to the second node N2, and a control electrode of the switching transistor is coupled to the general purpose input/output terminal GPIO. For example, the switching transistor comprises an N-type transistor or a P-type transistor.

The voltage regulator circuit 230 is configured to turn on the switching transistor in response to the first control signal DCtrl1 transmitted by the general purpose input/output terminal GPIO.

The above voltage regulator circuit 230 is connected in parallel at two ends of the fourth resistor, and in the case that the switching transistor is turned on in response to the first control signal DCtrl1 transmitted by the general purpose input/output terminal GPIO, the fourth resistor is short-circuited, characterizing that the resistor-capacitor circuit 210 comprises a first resistor (such as the first resistor 132 shown in FIG. 8), a second resistor (such as the second resistor 133 shown in FIG. 8), and a capacitor 211 (such as the capacitor 131 shown in FIG. 8). In this way, the resistance of the resistor-capacitor circuit 210 can be reduced, and the voltage across the capacitor 211 can be increased. Therefore, boost inspection can be performed on the capacitor 211 according to requirements.

It may be understood that the voltage regulator circuit 230 may also be connected in parallel at two ends of the first resistor or the second resistor, or at two ends of other electronic components connected in series in the resistor-capacitor circuit 210, which is not limited in the examples provided in the present disclosure.

Based on different examples of the positions where the voltage regulator circuit 230 and the resistor-capacitor circuit 210 are connected, in combination with the structure where the first control signal DCtrl1 is transmitted to the control electrode of the switching transistor of the voltage regulator circuit 230, the resistance of the voltage regulator circuit 230 may also be adjusted by adjusting the voltage value of the first control signal DCtrl1. Further, the resistance value of the equivalent impedance of the resistor-capacitor circuit 210 is adjusted.

In some examples, the electronic components and their connection relationships in the voltage regulator circuit 230 in the power loss protection system shown in FIG. 19 may be the same as those in the voltage regulator circuit 150 in the memory system 100 shown in FIG. 9. The voltage regulator circuit 230 is configured to adjust the resistance value of the equivalent impedance of the resistor-capacitor circuit 210 based on the voltage value of the first control signal DCtrl1.

For example, similar to the electronic components and their connection relationships in the voltage regulator circuit 150 in the memory system 100 shown in FIG. 9, the voltage regulator circuit 230 in the power loss protection system comprises a switching transistor (such as the switching transistor 151 shown in FIG. 9) and a third resistor (such as the third resistor 152 shown in FIG. 9) connected in series.

Based on different voltage values of the first control signal DCtrl1, the conduction degree of the switching transistor may be adjusted.

For example, the switching transistor comprises an N-type transistor. The voltage value of the first control signal DCtrl1 increases, the conduction degree of the switching transistor increases, and the equivalent resistance of the switching transistor decreases. The equivalent resistance of the voltage regulator circuit 230 is reduced. In this way, when the second resistor (such as the second resistor 133 shown in FIG. 9) is connected in parallel with the voltage regulator circuit 230, the equivalent resistance of the second resistor and the voltage regulator circuit 230 is also reduced, thereby reducing the equivalent impedance of the resistor-capacitor circuit 210. Based on this, the voltage across the capacitor 211 can be increased to a certain extent, which is beneficial to improving the control accuracy of the magnitude of the voltage across the capacitor 211, and can be applied to the detection of the state of health of the capacitor 211 with different capacities.

In some examples, as shown in FIG. 20, the control circuit 240 is configured to transmit the second control signal DCtrl2 to the power loss protection circuit 220, and drive the power loss protection circuit 220 to charge the capacitor 211 after adjusting the equivalent resistance to the target voltage DVg and discharge.

The control circuit 240 is further configured to determine the state of health of the capacitor 211 according to the voltage across the discharged capacitor 211 and the target voltage DVg.

For example, compared with the initial capacitance DVin of the capacitor 211, the target voltage DVg is greater than the initial capacitance DVin, the power loss protection circuit 220 charges the capacitor 211, and the amount of charges stored in the capacitor 211 increases.

The state of health of the capacitor 211 is determined according to the capacity calculation parameter of the capacitor 211, the target voltage DVg, and the voltage DVg_down across the discharged capacitor 211.

For example, the capacity calculation parameter of the capacitor 211 comprises a temperature coefficient of the capacitor 211, an attribute of a dielectric material between the two plates, and the like. According to the duration needed for the capacitor 211 to store the amount of charges corresponding to the target voltage DVg under the driving of the target voltage DVg (that is, after the power supply is turned off, the voltage across the capacitor 211 is kept at DVg); and the duration needed for, after the capacitor 211 is discharged, for example, the voltage DVg_down across the capacitor 211 reaches to 0V; the time constant τ = RC is calculated. If the calculated capacitance value differs significantly from the nominal value, it indicates that the state of health of the capacitor 211 is poor.

It should be noted that the state of health of the capacitor 211 may also be detected according to other parameters and determination logic. For example, whether the capacitor 211 is leaking may be determined according to the voltage holding time after charging the capacitor 211 to the amount of charges corresponding to the target voltage DVg. Whether the capacitor 211 is leaking may also be determined according to the speed at which the voltage across the capacitor 211 decreases during the process of the capacitor 211 starting to discharge from storing the amount of charges corresponding to the target voltage DVg. This is not limited in the examples provided in the present disclosure, and may be set according to actual requirements.

In some examples, the control circuit 240 is configured to turn off the voltage regulator circuit 230 based on completion of a detection operation of the resistor-capacitor circuit 210.

As shown in FIG. 20, the control circuit 240 is further configured to transmit the third control signal DCtrl3 to the power loss protection circuit 220, and control the power loss protection circuit 220 to charge the capacitor 211 of the resistor-capacitor circuit 210 to the initial voltage DVin based on the voltage regulator circuit 230 being turned off; the initial voltage DVin is less than the target voltage DVg; and the capacitor 211 is configured to store the power based on the initial voltage DVin.

For example, after the capacitor 211 is inspected, it may be determined that the capacitor 211 is in a good state of health. Then, the voltage regulator circuit 230 is turned off, the capacitor 211 can be continuously charged, and the capacitor 211 is charged by using the power loss protection circuit 220, providing a power for other circuits in the case that the power loss protection system is powered down.

In some examples, as shown in FIG. 20, the voltage regulator circuit 230 is coupled to the general purpose input/output terminal GPIO of the general purpose input/output interface circuit 250. The control circuit 240 is further configured to transmit the first control signal DCtrl1 to the voltage regulator circuit 230 through the general purpose input/output terminal GPIO every preset time interval T0.

For example, the general purpose input/output interface circuit 250 may comprise an interface circuit (General Purpose Input / Output, GPIO) widely used in an embedded system and a microcontroller, to implement interaction between the microcontroller and an external device. By configuring the working mode of the general purpose input/output interface circuit 250, different control signals are output from the general purpose input/output terminal GPIO.

For example, the control circuit 240 is configured to control the general purpose input/output interface circuit 250 to output the first control signal DCtrl1 from the general purpose input/output terminal GPIO to the voltage regulator circuit 230 every preset time interval T0.

In view of this, examples of the present disclosure provide a memory system, a control method thereof, and a power loss protection system, which can flexibly adjust the voltage across the capacitor, improve the detection accuracy of the state of health of the capacitor, and reduce the probability of data loss in case of power loss during capacitance inspection.

In one aspect, some examples of the present disclosure provide a memory system. The memory system comprises a non-volatile memory device, a volatile memory device, a resistor-capacitor circuit, a power loss protection circuit, a voltage regulator circuit, and a memory controller.

The resistor-capacitor circuit comprises a capacitor configured to provide power for driving writing data within the volatile memory device into the non-volatile memory device. The power loss protection circuit is coupled to the resistor-capacitor circuit and is configured to charge the capacitor. The voltage regulator circuit is coupled to the resistor-capacitor circuit and is configured to adjust an equivalent impedance of the resistor-capacitor circuit in response to a first control signal.

The memory controller is coupled to the voltage regulator circuit and the power loss protection circuit and is configured to output a first control signal to the voltage regulator circuit; and is further configured to acquire a capacitance of the capacitor after adjusting the equivalent impedance by using the power loss protection circuit to determine a state of health of the capacitor.

In some examples, the voltage regulator circuit is configured to adjust an equivalent impedance of the resistor-capacitor circuit from a first resistance value to a second resistance value in response to the first control signal; the first resistance value is greater than the second resistance value.

The power loss protection circuit is configured to charge the capacitor to a target voltage based on the equivalent impedance of the resistor-capacitor circuit being the second resistance value; the target voltage is greater than a voltage of the resistor-capacitor circuit before adjustment.

In some examples, the resistor-capacitor circuit is coupled to the power loss protection circuit through a first node and is coupled to a first power supply voltage terminal through a second node. The resistor-capacitor circuit comprises the capacitor, a first resistor, and a second resistor. One end of the first resistor is coupled to a first plate of the capacitor, and the other end of the first resistor is coupled to the first node. One end of the second resistor is coupled to the first node, and the other end of the second resistor is coupled to a second plate of the capacitor.

The voltage regulator circuit is connected in parallel with at least one of the first resistor or the second resistor and is configured to adjust the equivalent impedance of the resistor-capacitor circuit.

In some examples, the voltage regulator circuit comprises a switching transistor and a third resistor connected in series. A first electrode of the switching transistor is coupled to the first node, a second electrode of the switching transistor is coupled to one end of the third resistor, and a control electrode of the switching transistor is coupled to a general purpose input/output terminal. The other end of the third resistor is coupled to a second plate of the capacitor.

The voltage regulator circuit is configured to turn on the switching transistor in response to the first control signal transmitted by the general purpose input/output terminal, to connect the third resistor in parallel with the second resistor.

In some examples, the voltage regulator circuit comprises a switching transistor and a third resistor connected in series. A first electrode of the switching transistor is coupled to a first node, a second electrode of the switching transistor is coupled to one end of the third resistor, and a control electrode of the switching transistor is coupled to a general purpose input/output terminal. The other end of the third resistor is coupled to a first plate of the capacitor.

The voltage regulator circuit is configured to turn on the switching transistor in response to the first control signal transmitted by the general purpose input/output terminal, to connect the third resistor in parallel with the first resistor.

In some examples, the resistor-capacitor circuit is coupled to the power loss protection circuit through a first node, and is coupled to a first power supply voltage terminal through a second node. The resistor-capacitor circuit comprises the capacitor, a first resistor, a second resistor, and a fourth resistor. One end of the first resistor is coupled to a first plate of the capacitor, and the other end of the first resistor is coupled to the first node. One end of the second resistor is coupled to the first node, and the other end of the second resistor is coupled to a third node. One end of the fourth resistor is coupled to the third node, and the other end of the fourth resistor is coupled to the second plate of the capacitor through the second node.

The voltage regulator circuit comprises a switching transistor, a first electrode of the switching transistor is coupled to the third node, a second electrode of the switching transistor is coupled to the second node, and a control electrode of the switching transistor is coupled to a general purpose input/output terminal. The voltage regulator circuit is configured to turn on the switching transistor in response to the first control signal transmitted by the general purpose input/output terminal.

In some examples, the switching transistor comprises an N-type transistor or a P-type transistor.

In some examples, the voltage regulator circuit is configured to adjust a resistance value of the equivalent impedance of the resistor-capacitor circuit based on a voltage value of the first control signal.

In some examples, the memory controller is configured to output a second control signal to the power loss protection circuit, and drive the power loss protection circuit to charge the capacitor after adjusting the equivalent resistance of the resistor-capacitor circuit to a target voltage and discharge. The memory controller is further configured to determine the state of health of the capacitor according to the voltage across the discharged capacitor and the target voltage.

In some examples, the memory controller is configured to turn off the voltage regulator circuit based on completion of a detection operation of the resistor-capacitor circuit. The memory controller is further configured to output a third control signal to the power loss protection circuit, and control the power loss protection circuit to charge the capacitor of the resistor-capacitor circuit to an initial voltage based on the voltage regulator circuit being turned off; the initial voltage is less than the target voltage.

The power loss protection circuit is further configured to maintain the non-volatile memory device to perform operation of reading/writing data for a first duration by utilizing a power stored in the capacitor based on the initial voltage.

In some examples, the voltage regulator circuit is coupled to a general purpose input/output terminal of the general purpose input/output interface circuit. The memory controller is further configured to transmit the first control signal to the voltage regulator circuit through the general purpose input/output terminal every preset time interval.

In some examples, the resistor-capacitor circuit comprises a plurality of the capacitors connected in series.

In some examples, the non-volatile memory device comprises a NAND memory device. The volatile memory device comprises a DRAM memory device.

In the above memory system, the inspection operation of the capacitor can be actively performed based on the first control signal, and the flexible control of the user on the capacitor inspection operation can be improved. By adjusting the equivalent impedance of the resistor-capacitor circuit through the voltage regulator circuit, the voltage magnitude across the capacitor (without exceeding the rated voltage of the capacitor) can be flexibly adjusted according to different requirements, and not limited by the circuit structure where the capacitor is located (for example, the circuit connection relationship and structure of the resistor-capacitor circuit), for example, without changing other integrated circuit structures, the voltage across the capacitor can be increased to different extent, or the voltage across the capacitor can be reduced to different extent, so as to detect the capacity of the capacitor to store charges under different conditions, and improve the detection precision of the state of health of the capacitor. Moreover, in the case of supporting boost inspection, even if power loss occurs in the inspection process, the amount of charges stored in the capacitor is large, the non-volatile memory device can be supported for data storage, and the probability of data loss is reduced.

In another aspect, some examples of the present disclosure provide a control method of a memory system. The memory system comprises a non-volatile memory device, a volatile memory device, a memory controller, a resistor-capacitor circuit, a power loss protection circuit, and a voltage regulator circuit; the non-volatile memory device and the volatile memory device are coupled to the memory controller; the resistor-capacitor circuit is coupled to the non-volatile memory device, the volatile memory device, the memory controller, the power loss protection circuit, and the voltage regulator circuit.

The control method comprises: adjusting, by the voltage regulator circuit, an equivalent impedance of the resistor-capacitor circuit in response to a first control signal; and performing a capacitance inspection operation based on a capacitance of the capacitor after adjusting the equivalent impedance of the resistor-capacitor circuit.

In some examples, the control method further comprises: transmitting, by the memory controller, the first control signal to the voltage regulator circuit every preset time interval.

The adjusting, by the voltage regulator circuit, the equivalent impedance of the resistor-capacitor circuit in response to the first control signal comprises: adjusting, by the voltage regulator circuit, the equivalent impedance of the resistor-capacitor circuit from a first resistance value to a second resistance value in response to the first control signal; the second resistance value is less than the first resistance value.

In some examples, the adjusting, by the voltage regulator circuit, the equivalent impedance of the resistor-capacitor circuit in response to the first control signal comprises: adjusting, by the voltage regulator circuit, a magnitude of the second resistance value based on a voltage of the first control signal.

In some examples, the control method comprises: transmitting, by the memory controller, a second control signal to the power loss protection circuit based on the adjusted equivalent resistance of the resistor-capacitor circuit.

The determining a state of health of the capacitor based on the capacitance of the capacitor after adjusting the equivalent impedance of the resistor-capacitor circuit comprises: discharging, by the power loss protection circuit, after charging the capacitor of the resistor-capacitor circuit to the target voltage in response to the second control signal, acquiring a target voltage and a post-discharge voltage across the capacitor, and determining the state of health of the capacitor according to a capacity calculation parameter, the target voltage, and the post-discharge voltage of the capacitor.

In some examples, the control method further comprises: controlling, by the memory controller, the voltage regulator circuit to be turned off based on completion of the detection operation of the resistor-capacitor circuit, and outputting a third control signal to the power loss protection circuit. The power loss protection circuit charges the capacitor of the resistor-capacitor circuit to an initial voltage in response to the third control signal.

When the memory controller is abnormally powered down, the resistor-capacitor circuit maintains the non-volatile memory device to perform operation of reading/writing data for a first duration by utilizing a power stored based on the initial voltage.

In some examples, the control method further comprises: storing a detection result based on completion of a detection operation of the resistor-capacitor circuit, and performing an early warning prompt.

The beneficial effects of the control method of the above memory system are the same as the beneficial effects of the memory system provided in any one of the above examples, and details are not described herein again.

In still another aspect, examples of the present disclosure provide a power loss protection system. The power loss protection system comprises a resistor-capacitor circuit, a power loss protection circuit, a voltage regulator circuit and a control circuit.

The resistor-capacitor circuit comprises a capacitor configured to provide a power. The power loss protection circuit is coupled to the resistor-capacitor circuit and is configured to charge the capacitor. The voltage regulator circuit is coupled to the resistor-capacitor circuit and is configured to adjust an equivalent impedance of the resistor-capacitor circuit in response to a first control signal.

The control circuit is coupled to the voltage regulator circuit and the power loss protection circuit and is configured to output the first control signal to the voltage regulator circuit; and is further configured to acquire a capacitance of the capacitor after adjusting the equivalent impedance by using the power loss protection circuit to determine a state of health of the capacitor.

In some examples, the voltage regulator circuit is configured to adjust an equivalent impedance of the resistor-capacitor circuit from a first resistance value to a second resistance value in response to the first control signal; the first resistance value is greater than the second resistance value.

The power loss protection circuit is configured to charge the capacitor to a target voltage based on the equivalent impedance of the resistor-capacitor circuit being the second resistance value; the target voltage is greater than a voltage of the resistor-capacitor circuit before adjustment.

In some examples, the resistor-capacitor circuit is coupled to the power loss protection circuit through a first node and is coupled to a first power supply voltage terminal through a second node. The resistor-capacitor circuit comprises the capacitor, a first resistor, and a second resistor. One end of the first resistor is coupled to a first plate of the capacitor, and the other end of the first resistor is coupled to the first node. One end of the second resistor is coupled to the first node, and the other end of the second resistor is coupled to a second plate of the capacitor.

The voltage regulator circuit is connected in parallel with at least one of the first resistor or the second resistor and is configured to adjust the equivalent impedance of the resistor-capacitor circuit.

In some examples, the voltage regulator circuit comprises a switching transistor and a third resistor connected in series. A first electrode of the switching transistor is coupled to the first node, a second electrode of the switching transistor is coupled to one end of the third resistor, and a control electrode of the switching transistor is coupled to a general purpose input/output terminal. The other end of the third resistor is coupled to a second plate of the capacitor.

The voltage regulator circuit is configured to turn on the switching transistor in response to the first control signal transmitted by the general purpose input/output terminal, to connect the third resistor in parallel with the second resistor.

In some examples, the voltage regulator circuit comprises a switching transistor and a third resistor connected in series. A first electrode of the switching transistor is coupled to a first node, a second electrode of the switching transistor is coupled to one end of the third resistor, and a control electrode of the switching transistor is coupled to a general purpose input/output terminal. The other end of the third resistor is coupled to a first plate of the capacitor.

The voltage regulator circuit is configured to turn on the switching transistor in response to the first control signal transmitted by the general purpose input/output terminal, to connect the third resistor in parallel with the first resistor.

In some examples, the resistor-capacitor circuit is coupled to the power loss protection circuit through a first node, and is coupled to a first power supply voltage terminal through a second node. The resistor-capacitor circuit comprises the capacitor, a first resistor, a second resistor, and a fourth resistor. One end of the first resistor is coupled to a first plate of the capacitor, and the other end of the first resistor is coupled to the first node. One end of the second resistor is coupled to the first node, and the other end of the second resistor is coupled to a third node. One end of the fourth resistor is coupled to the third node, and the other end of the fourth resistor is coupled to the second plate of the capacitor through the second node.

The voltage regulator circuit comprises a switching transistor, a first electrode of the switching transistor is coupled to the third node, a second electrode of the switching transistor is coupled to the second node, and a control electrode of the switching transistor is coupled to a general purpose input/output terminal. The voltage regulator circuit is configured to turn on the switching transistor in response to the first control signal transmitted by the general purpose input/output terminal.

In some examples, the switching transistor comprises an N-type transistor or a P-type transistor.

In some examples, the voltage regulator circuit is configured to adjust a resistance value of the equivalent impedance of the resistor-capacitor circuit based on a voltage value of the first control signal.

In some examples, the control circuit is configured to transmit a second control signal to the power loss protection circuit, and drive the power loss protection circuit to charge the capacitor after adjusting the equivalent resistance to a target voltage and discharge. The control circuit is further configured to determine the state of health of the capacitor according to the voltage across the discharged capacitor and the target voltage.

In some examples, the control circuit is configured to turn off the voltage regulator circuit based on completion of a detection operation of the resistor-capacitor circuit. The control circuit is further configured to transmit a third control signal to the power loss protection circuit, and control the power loss protection circuit to charge the capacitor of the resistor-capacitor circuit to an initial voltage based on the voltage regulator circuit being turned off; the initial voltage is less than the target voltage; the capacitor is configured to store a power based on the initial voltage.

In some examples, the voltage regulator circuit is coupled to a general purpose input/output terminal of the general purpose input/output interface circuit. The control circuit is further configured to transmit the first control signal to the voltage regulator circuit through the general purpose input/output terminal every preset time interval.

In some examples, the resistor-capacitor circuit comprises a plurality of the capacitors connected in series.

The beneficial effects of the above power loss protection system are the same as the beneficial effects of the memory system provided in any one of the above examples, and details are not described herein again.

The above descriptions are only implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is Claimed Is:

1. A memory system, comprising:
a non-volatile memory device;
a volatile memory device,
a resistor-capacitor circuit including a capacitor configured to provide power to write data from the volatile memory device to the non-volatile memory device;
a power loss protection circuit coupled to the resistor-capacitor circuit and configured to charge the capacitor;
a voltage regulator circuit coupled to the resistor-capacitor circuit and configured to adjust an equivalent impedance of the resistor-capacitor circuit in response to a first control signal; and
a memory controller coupled to the voltage regulator circuit and the power loss protection circuit and configured to:
output the first control signal to the voltage regulator circuit; and
determine a state of health of the capacitor based on after a capacitance of the capacitor acquired by using the power loss protection circuit after adjusting the equivalent impedance .

2. The memory system of claim 1, wherein:
the voltage regulator circuit is configured to adjust the equivalent impedance of the resistor-capacitor circuit from a first resistance value to a second resistance value in response to the first control signal; wherein the first resistance value is greater than the second resistance value; and
the power loss protection circuit is configured to charge the capacitor to a target voltage based on the equivalent impedance of the resistor-capacitor circuit being the second resistance value; wherein the target voltage is greater than a voltage of the resistor-capacitor circuit before adjustment.

3. The memory system of claim 1, wherein:
the resistor-capacitor circuit is coupled to the power loss protection circuit through a first node and is coupled to a first power supply voltage terminal through a second node;
the resistor-capacitor circuit comprises the capacitor, a first resistor, and a second resistor;
one end of the first resistor is coupled to a first plate of the capacitor, and the other end of the first resistor is coupled to the first node;
one end of the second resistor is coupled to the first node, and the other end of the second resistor is coupled to a second plate of the capacitor; and
the voltage regulator circuit is connected in parallel with at least one of the first resistor or the second resistor and is configured to adjust the equivalent impedance of the resistor-capacitor circuit.

4. The memory system of claim 3, wherein:
the voltage regulator circuit comprises a switching transistor and a third resistor connected in series;
a first electrode of the switching transistor is coupled to the first node, a second electrode of the switching transistor is coupled to one end of the third resistor, and a control electrode of the switching transistor is coupled to a general purpose input/output terminal;
the other end of the third resistor is coupled to the second plate of the capacitor; and
the voltage regulator circuit is configured to turn on the switching transistor in response to the first control signal transmitted by the general purpose input/output terminal, to connect the third resistor in parallel with the second resistor.

5. The memory system of claim 4, wherein the switching transistor comprises an N-type transistor or a P-type transistor.

6. The memory system of claim 4, wherein the voltage regulator circuit is configured to adjust a resistance value of the equivalent impedance of the resistor-capacitor circuit based on a voltage value of the first control signal.

7. The memory system of claim 3, wherein:
the voltage regulator circuit comprises a switching transistor and a third resistor connected in series;
a first electrode of the switching transistor is coupled to the first node, a second electrode of the switching transistor is coupled to one end of the third resistor, and a control electrode of the switching transistor is coupled to a general purpose input/output terminal;
the other end of the third resistor is coupled to the first plate of the capacitor; and
the voltage regulator circuit is configured to turn on the switching transistor in response to the first control signal transmitted by the general purpose input/output terminal, to connect the third resistor in parallel with the first resistor.

8. The memory system of claim 1, wherein the resistor-capacitor circuit is coupled to the power loss protection circuit through a first node, and is coupled to a first power supply voltage terminal through a second node;
the resistor-capacitor circuit comprises the capacitor, a first resistor, a second resistor, and a fourth resistor;
one end of the first resistor is coupled to a first plate of the capacitor, and the other end of the first resistor is coupled to the first node;
one end of the second resistor is coupled to the first node, and the other end of the second resistor is coupled to a third node;
one end of the fourth resistor is coupled to the third node, and the other end of the fourth resistor is coupled to a second plate of the capacitor through the second node;
the voltage regulator circuit comprises a switching transistor, a first electrode of the switching transistor is coupled to the third node, a second electrode of the switching transistor is coupled to the second node, and a control electrode of the switching transistor is coupled to a general purpose input/output terminal; and
the voltage regulator circuit is configured to turn on the switching transistor in response to the first control signal transmitted by the general purpose input/output terminal.

9. The memory system of claim 1, wherein:
the memory controller is configured to output a second control signal to the power loss protection circuit, to control the power loss protection circuit to charge the capacitor after adjusting the equivalent resistance of the resistor-capacitor circuit to a target voltage and discharge after charging the capacitor to target voltage; and
the memory controller is further configured to determine the state of health of the capacitor according to the voltage across the discharged capacitor and the target voltage.

10. The memory system of claim 9, wherein:
the memory controller is configured to turn off the voltage regulator circuit based on completion of a detection operation of the resistor-capacitor circuit; and
the memory controller is further configured to output a third control signal to the power loss protection circuit, to control the power loss protection circuit to charge the capacitor of the resistor-capacitor circuit to an initial voltage based on the voltage regulator circuit being turned off; wherein the initial voltage is less than the target voltage; and
the power loss protection circuit is further configured to maintain the non-volatile memory device to perform operation of reading/writing data for a first duration by utilizing a power stored in the capacitor based on the initial voltage.

11. The memory system of claim 1, wherein the voltage regulator circuit is coupled to a general purpose input/output terminal of a general purpose input/output interface circuit; and
the memory controller is further configured to transmit the first control signal to the voltage regulator circuit through the general purpose input/output terminal every preset time interval.

12. The memory system of claim 1, wherein the resistor-capacitor circuit comprises a plurality of the capacitors connected in series.

13. The memory system of claim 1, wherein the non-volatile memory device comprises a NAND memory device; and
the volatile memory device comprises a DRAM memory device.

14. A method of controlling a memory system, wherein the memory system comprises a non-volatile memory device, a volatile memory device, a memory controller, a resistor-capacitor circuit, a power loss protection circuit, and a voltage regulator circuit; the non-volatile memory device and the volatile memory device are coupled to the memory controller; the resistor-capacitor circuit is coupled to the non-volatile memory device, the volatile memory device, the memory controller, the power loss protection circuit, and the voltage regulator circuit;
the control method comprises:
adjusting, by the voltage regulator circuit, an equivalent impedance of the resistor-capacitor circuit in response to a first control signal; and
performing a capacitance inspection operation based on a capacitance of a capacitor after adjusting the equivalent impedance of the resistor-capacitor circuit.

15. The method of claim 14, further comprising:
transmitting, by the memory controller, the first control signal to the voltage regulator circuit every preset time interval; and
the adjusting, by the voltage regulator circuit, the equivalent impedance of the resistor-capacitor circuit in response to the first control signal comprises:
adjusting, by the voltage regulator circuit, the equivalent impedance of the resistor-capacitor circuit from a first resistance value to a second resistance value in response to the first control signal; wherein the second resistance value is less than the first resistance value.

16. The method of claim 15, wherein the adjusting, by the voltage regulator circuit, the equivalent impedance of the resistor-capacitor circuit in response to the first control signal comprises:
adjusting, by the voltage regulator circuit, a magnitude of the second resistance value based on a voltage of the first control signal.

17. The method of claim 14, comprising:
transmitting, by the memory controller, a second control signal to the power loss protection circuit based on the adjusted equivalent resistance of the resistor-capacitor circuit;
the determining a state of health of the capacitor based on the capacitance of the capacitor after adjusting the equivalent impedance of the resistor-capacitor circuit comprises:
discharging, by the power loss protection circuit, after charging the capacitor of the resistor-capacitor circuit to a target voltage in response to the second control signal;
acquiring the target voltage and a post-discharge voltage across the capacitor; and
determining the state of health of the capacitor according to a capacity calculation parameter, the target voltage, and the post-discharge voltage of the capacitor.

18. The method of claim 14, further comprising:
based on completion of a detection operation of the resistor-capacitor circuit , by the memory controller, controlling the voltage regulator circuit to be turned off and outputting a third control signal to the power loss protection circuit;
charging, by the power loss protection circuit, the capacitor of the resistor-capacitor circuit to an initial voltage in response to the third control signal; and
when the memory controller is abnormally powered down, maintaining, by the resistor-capacitor circuit, the non-volatile memory device to perform operation of reading/writing data for a first duration by utilizing a power stored based on the initial voltage.

19. The method of claim 14, further comprising:
storing a detection result based on completion of a detection operation of the resistor-capacitor circuit, and performing an early warning prompt.

20. A power loss protection system, comprising
a resistor-capacitor circuit including a capacitor configured to provide a power;
a power loss protection circuit coupled to the resistor-capacitor circuit and configured to charge the capacitor;
a voltage regulator circuit coupled to the resistor-capacitor circuit and configured to adjust an equivalent impedance of the resistor-capacitor circuit in response to a first control signal; and
a control circuit coupled to the voltage regulator circuit and the power loss protection circuit and configured to:
output the first control signal to the voltage regulator circuit; and
determine a state of health of the capacitor based on a capacitance of the capacitor acquired by using the power loss protection circuit after adjusting the equivalent impedance .
